(19) United States
(12) Patent Application Publication
(10) Pub. No.: US 2024/0052485 A1
(43) Pub. Date: Feb. 15, 2024

(54) APPARATUS AND METHODS FOR COMBINATORIAL MATERIAL SCREENING AND DISCOVERY

(71) Applicant: The University of British Columbia, Vancouver (CA)

(72) Inventors: Konrad WALUS, Vancouver (CA); Anindya LaI ROY, Vancouver (CA)

(21) Appl. No.: 18/458,088

(22) Filed: Aug. 29, 2023

Related U.S. Application Data
(63) Continuation of application No. PCT/CA2022/050310, filed on Mar. 3, 2022.
(60) Provisional application No. 63/155,970, filed on Mar. 3, 2021.

(51) Int. Cl. C23C 16/455; C23C 14/24; C23C 14/58

(52) U.S. Cl. CPC C23C 16/45514; C23C 14/24; C23C 14/5806

(57) ABSTRACT

A method of combinatorial material screening comprising causing first and second precursors to travel through a mixing channel to form a first mixture, depositing the first mixture onto a substrate to form a first thin film in a first pattern, causing more of the first and second precursors to travel through the mixing channel to form a second mixture, depositing the second mixture onto the substrate to form a second thin film in a second pattern comparing one or more characteristics of the first and second thin films.

### REFERENCE TO RELATED APPLICATIONS

This application is a continuation of Patent Cooperation Treaty (PCT) application No. PCT/CA2022/050310 having an international filing date of 3 Mar. 2022, which in turn claims priority from, and for the purposes of the United States of America the benefit under 35 USC 119 in connection with, U.S. application No. 63/155,970 filed 3 Mar. 2021 which is hereby incorporated herein by reference.

### TECHNICAL FIELD

This application relates to apparatus and methods for combinatorial material screening and discovery. Particular non-limiting embodiments provide apparatus and methods for printing and testing thin film material formulations.

### BACKGROUND

There is a desire for alternative thin film material formulations for use in, for example, electroactive components (conductors, semiconductors and dielectrics) which may be used in, for example, chemical and biological sensors, actuators, photovoltaics, thermo-electrics, ferroelectrics and printable/flexible electronics. Such alternative formulations may comprise combinations of organic polymers, stoichiometric alloys, biomaterials, carbon allotropes, quantum dots and other novel chemical systems. However, due the large number of possible combinations and the unknown interactions that may occur when such combinations are formed, it is difficult address this problem analytically.

There is a general desire for methods and apparatus for efficiently creating and testing thin films having various formulations.

The foregoing examples of the related art and limitations related thereto are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

One aspect of the invention provides a method of combinatorial material screening. The method comprises: causing a first volume of a first precursor to travel through a first precursor channel into a mixing channel; causing a second volume of a second precursor to travel through a second precursor channel into the mixing channel; causing the first and second volumes of the first and second precursors to travel through the mixing channel to form a first mixture; depositing the first mixture onto a substrate to form a first thin film in a first pattern; causing a third volume of the first precursor to travel through the first precursor channel into the mixing channel; causing a fourth volume of the second precursor to travel through the second precursor channel into the mixing channel; causing the third and fourth volumes of the first and second precursors to travel through the mixing channel to form a second mixture; depositing the second mixture onto the substrate to form a second thin film in a second pattern; and comparing one or more characteristics of the first and second thin films.

The first precursor channel may comprise a first microfluidic channel, the second precursor channel may comprise a second microfluidic channel and the mixing channel may comprise a microfluidic mixing channel.

The first microfluidic channel may have a first cross-sectional area of between 100 μm² and 250,000 μm², the second microfluidic channel may have a second cross-sectional area of between 100 μm² and 250,000 μm², and the third microfluidic channel may have a third cross-sectional area of between 200 μm² and 500,000 μm².

The first microfluidic channel may have a first cross-sectional area of between 100 μm² and 10,000 μm², the second microfluidic channel may have a second cross-sectional area of between 100 μm² and 10,000 μm², and the third microfluidic channel may have a third cross-sectional area of between 200 μm² and 20,000 μm².

Causing the first volume of the first precursor to travel through the first precursor channel may comprise controlling a first flow rate of the first precursor. Causing the second volume of a second precursor to travel through the second precursor channel may comprise controlling a second flow rate of the second precursor. Causing the third volume of the first precursor to travel through the first precursor channel may comprise controlling a third flow rate of the first precursor. Causing the fourth volume of the second precursor to travel through the second precursor channel may comprise controlling a fourth flow rate of the second precursor.

Controlling the first flow rate of the first precursor may comprise controllably actuating a first syringe pump to force the first precursor into the first precursor channel at the first flow rate for a first period of time. Controlling the second flow rate of the second precursor may comprise controllably actuating a second syringe pump to force the second precursor into the second precursor channel at the second flow rate for a second period of time. Controlling the third flow rate of the first precursor may comprise controllably actuating the first syringe pump to force the first precursor into the first precursor channel at the third flow rate for a third period of time. Controlling the fourth flow rate of the second precursor may comprise controllably actuating the second syringe pump to force the second precursor into the second precursor channel at the fourth flow rate for a fourth period of time.

Controlling the first flow rate of the first precursor may comprise controllably actuating a first syringe pump to force the first precursor into the first precursor channel based at least in part on feedback from a first sensor. Controlling the second flow rate of the second precursor may comprise controllably actuating a second syringe pump to force the second precursor into the second precursor channel based at least in part on feedback from a second sensor. Controlling the third flow rate of the first precursor may comprise controllably actuating the first syringe pump to force the first precursor into the first precursor channel based at least in part on feedback from the first sensor. Controlling the fourth flow rate of the second precursor may comprise controllably actuating the second syringe pump to force the second precursor into the second precursor channel based at least in part on feedback from the second sensor.

The method may comprise flushing the mixing channel after depositing the first mixture onto the substrate. Flushing the mixing channel may comprise flushing water through the mixing channel.

After depositing the second mixture onto the substrate, the first mixture and the deposited mixture may be heated to form the first thin film and the second thin film.

After depositing the second mixture onto the substrate, the first mixture and the deposited mixture may be heated in a vacuum oven to form the first thin film and the second thin film.

After depositing the second mixture onto the substrate, the first mixture and the deposited mixture may be subjected to ultraviolet light to form the first thin film and the second thin film.

Depositing the first mixture onto the substrate to form the first thin film in the first pattern may comprise ejecting the first mixture through a nozzle and patterning the ejected first mixture onto the substrate with first magnetic fields. Depositing the second mixture onto the substrate to form the second thin film in the second pattern may comprise ejecting the second mixture through the nozzle and patterning the ejected second mixture onto the substrate with second magnetic fields.

Depositing the first mixture onto the substrate to form the first thin film in the first pattern may comprise inkjet printing the first mixture onto the substrate. Depositing the second mixture onto the substrate to form the second thin film in the second pattern may comprise inkjet printing the second mixture onto the substrate.

Depositing the first mixture onto the substrate to form the first thin film in the first pattern may comprise thermal triggered drop-on-demand printing the first mixture onto the substrate. Depositing the second mixture onto the substrate to form the second thin film in the second pattern may comprise thermal triggered drop-on-demand printing the second mixture onto the substrate.

Depositing the first mixture onto the substrate to form the first thin film in the first pattern may comprise piezoelectric triggered drop-on-demand printing the first mixture onto the substrate. Depositing the second mixture onto the substrate to form the second thin film in the second pattern may comprise piezoelectric triggered drop-on-demand printing the second mixture onto the substrate.

At least a portion of the step of depositing the first mixture onto the substrate may overlap temporally with the step of causing the first and second volumes of the first and second precursors to travel through the mixing channel. At least a portion of the step of depositing the second mixture onto the substrate may overlap temporally with the step of causing the third and fourth volumes of the first and second precursors to travel through the mixing channel.

The first mixture may have a first ratio of the first precursor to the second precursor and the second mixture may have a second ratio of the first precursor to the second precursor. The second ratio may be different from the first ratio.

The method may comprise causing a fifth volume of a third precursor to travel through a third precursor channel into the mixing channel wherein causing the first and second volumes of the first and second precursors to travel through the mixing channel comprises causing the first, second and fifth volumes of the first, second and third precursors respectively to travel through the mixing channel to form the first mixture. The method may comprise causing a sixth volume of the third precursor to travel through the third precursor channel into the mixing channel wherein causing the third and fourth volumes of the first and second precursors to travel through the mixing channel comprises causing the third, fourth and sixth volumes of the first, second and third precursors respectively to travel through the mixing channel to form the second mixture.

The substrate may comprise a plurality of electrodes. Depositing the first mixture onto the substrate to form the first thin film in the first pattern may comprise connecting first and second electrodes of the plurality of electrodes with the first mixture to thereby connect the first and second electrodes with the first thin film. Depositing the second mixture onto the substrate to form the second thin film in the second pattern may comprise connecting third and fourth electrodes of the plurality of electrodes with the second mixture to thereby connect the third and fourth electrodes with the second thin film.

The first thin film connecting the first and second electrodes may have a first width and a first thickness. The second thin film connecting the third and fourth electrodes may have a second width and a second thickness. The first width may be different from the second width. The first thickness may be different from the second thickness.

The one or more characteristics may comprise electrical characteristics.

Comparing the one or more characteristics of the first and second thin films may comprise determining a first resistance between the first and second electrodes and a second resistance between the third and fourth electrodes.

Comparing the one or more characteristics of the first and second thin films may comprise determining a first conductivity based at least in part on the first width, the first thickness and the first resistance and determining a second conductivity based at least in part on the second width, the second thickness and the second resistance and comparing the first conductivity to the second conductivity.

Comparing the one or more characteristics of the first and second thin films may comprise determining a first resistivity based at least in part on the first width, the first thickness and the first resistance and determining a second resistivity based at least in part on the second width, the second thickness and the second resistance and comparing the first resistivity to the second resistivity.

The one or more characteristics may comprise physical characteristics. The physical characteristics may comprise surface hardness. The physical characteristics may comprise surface roughness. The physical characteristics may comprise Young's Modulus.

The one or more characteristics may comprise time to set.

The one or more characteristics may comprise degree of cross-linking.

The one or more characteristics may comprise energy required to set.

The one or more characteristic may comprise morphological characteristics.

The one or more characteristics may comprise suitability for patterning.

The one or more characteristics may comprise suitability for depositing by inkjet printing.

The one or more characteristics may comprise suitability for depositing by thermal triggered drop-on-demand printing.

The one or more characteristics may comprise suitability for depositing by piezoelectric triggered drop-on-demand printing.

Depositing the second mixture onto the substrate to form the second thin film in the second pattern may comprise depositing the second mixture on top of at least a portion of the first thin film on the substrate in the second pattern.

Causing the first and second volumes of the first and second precursors to travel through the mixing channel to form the first mixture may comprise allowing the first and second precursors to passively mix in the first mixing channel to form the first mixture. Causing the third and fourth volumes of the first and second precursors to travel through the mixing channel to form the second mixture may comprise allowing the first and second precursors to passively mix in the first mixing channel to form the second mixture.

Causing the first and second volumes of the first and second precursors to travel through the mixing channel to form the first mixture may comprise actively mixing the first and second precursors in the first mixing channel to form the first mixture. Causing the third and fourth volumes of the first and second precursors to travel through the mixing channel to form the second mixture may comprise actively mixing the first and second precursors in the first mixing channel to form the second mixture.

Causing the first and second volumes of the first and second precursors to travel through the mixing channel to form the first mixture may comprise agitating the first and second precursors in the first mixing channel to form the first mixture. Causing the third and fourth volumes of the first and second precursors to travel through the mixing channel to form the second mixture may comprise agitating the first and second precursors in the first mixing channel to form the second mixture.

Causing the first and second volumes of the first and second precursors to travel through the mixing channel to form the first mixture may comprise vibrating the first and second precursors in the first mixing channel to form the first mixture. Causing the third and fourth volumes of the first and second precursors to travel through the mixing channel to form the second mixture may comprise vibrating the first and second precursors in the first mixing channel to form the second mixture.

causing the first and second volumes of the first and second precursors to travel through the mixing channel to form the first mixture may comprise mixing the first and second precursors in the first mixing channel by non-contact mixing to form the first mixture. Causing the third and fourth volumes of the first and second precursors to travel through the mixing channel to form the second mixture may comprise mixing the first and second precursors in the first mixing channel by non-contact mixing to form the second mixture.

Mixing the first and second precursors in the first mixing channel by non-contact mixing to form the first mixture may comprise actuating a non-contact mixer adjacent to the mixing channel. Mixing the first and second precursors in the first mixing channel by non-contact mixing to form the second mixture may comprise actuating the non-contact mixer.

The non-contact mixer may comprise a haptic motor.

Actuating the non-contact mixer may comprise causing the mixing channel to vibrate.

The first precursor may comprise a solution or a stabilized dispersion of one or more of an inorganic polymer, an organic polymer, an inorganic compound, an organometallic compound, a stoichiometric alloy (and/or components thereof), a biomaterial, a carbon allotrope and quantum dots.

The second precursor may comprise one or more of an organic surfactant, an inorganic surfactant, a co-solvent, a binder and a diluent.

Depositing the first mixture onto the substrate to form the first thin film in the first pattern may comprise controllably moving a printhead in one or more of x-, y- and z-directions to deposit the first mixture onto the substrate to form the first thin film in the first pattern. Depositing the second mixture onto the substrate to form the second thin film in the second pattern may comprise controllably moving the printhead in one or more of the x-, y- and z-directions to deposit the second mixture onto the substrate to form the second thin film in the second pattern.

Depositing the first mixture onto the substrate to form the first thin film in the first pattern may comprise controllably moving a stage supporting the substrate in one or more of x-, y- and z-directions to deposit the first mixture onto the substrate to form the first thin film in the first pattern. Depositing the second mixture onto the substrate to form the second thin film in the second pattern may comprise controllably moving the stage in one or more of the x-, y- and z-directions to deposit the second mixture onto the substrate to form the second thin film in the second pattern.

Another aspect of the invention provides a printhead for depositing material mixtures onto a substrate. The printhead comprises: a body-defining a first precursor channel, a second precursor channel and a mixing channel; a first pump for forcing a controllable first volume of a first precursor through the first precursor channel into the mixing channel; a second pump for forcing a controllable second volume of a second precursor through the second precursor channel into the mixing channel; a mixer arranged to mix the first and second volumes of the first and second precursors in the mixing channel to form a first mixture; and a dispenser for controllably depositing the first mixture onto the substrate in a first pattern.

The dispenser may comprise a drop-on-demand dispenser. The dispenser may comprise a thermal triggered drop-on-demand dispenser. The dispenser may comprise a piezoelectric drop-on-demand dispenser. The dispenser may comprise an inkjet dispenser.

The first precursor channel may comprise a first microfluidic channel. The second precursor channel may comprise a second microfluidic channel. The mixing channel may comprise a microfluidic mixing channel.

The first microfluidic channel may have a first cross-sectional area of between 100 μm² and 250,000 μm². The second microfluidic channel may have a second cross-sectional area of between 100 μm² and 250,000 μm². The third microfluidic channel may have a third cross-sectional area of between 200 μm² and 500,000 μm².

The first microfluidic channel may have a first cross-sectional area of between 100 μm² and 10,000 μm². The second microfluidic channel may have a second cross-sectional area of between 100 μm² and 10,000 μm². The third microfluidic channel may have a third cross-sectional area of between 200 μm² and 20,000 μm².

The mixer may comprise a contact mixer. The mixer may comprise a non-contact mixer.

The mixer may comprise a haptic motor arranged adjacent to the mixing channel to controllably vibrate contents of the mixing channel.

The mixer may comprise a piezoelectric actuator arranged adjacent to the mixing channel to controllably vibrate contents of the mixing channel.

The mixer may comprise a surface acoustic wave actuator arranged adjacent to the mixing channel to controllably vibrate contents of the mixing channel.

The body may define a third channel. The printhead may comprise: a third pump for forcing a controllable third volume of a third precursor through a third precursor channel into the mixing channel. The mixer may be arranged to mix the first, second and third volumes of the first, second and third precursors in the mixing channel to form the first mixture.

The body may comprise an elastomeric material.

The body may be 3D printed.

The first pump may comprise a first syringe pump. The second pump may comprise a second syringe pump.

The first pump may comprise a first flow controlled pump. The second pump may comprise a second flow controlled pump.

The first pump may comprise a first pressure controlled pump. The second pump may comprise a second pressure controlled pump.

The printhead may comprise a first sensor to provide feedback to the first pump to control a first rate of the first precursor through the first precursor channel. The printhead may comprise a second sensor to provide feedback to the first pump to control a second rate of the second precursor through the second precursor channel.

Another aspect of the invention provides a combinatorial printer comprising: any of the printheads described herein attached to a first actuator to controllably cause z-direction movement of the printhead; and a moveable stage for supporting the substrate wherein the moveable stage is attached to one or more second actuators to controllably cause x- and y-direction movement of the moveable stage; wherein the x-, y- and z-directions are mutually orthogonal.

Another aspect of the invention provides a combinatorial printer comprising: any of the printheads described herein attached to one or more actuators to controllably cause x-, y- and z-direction movement of the printhead; wherein the x-, y- and z-directions are mutually orthogonal.

Another aspect of the invention provides a combinatorial printer comprising: any of the printheads described herein; and a moveable stage for supporting the substrate wherein the moveable stage is attached to one or more actuators to controllably cause x-, y- and z-direction movement of the moveable stage; wherein the x-, y- and z-directions are mutually orthogonal.

Other aspects of the invention provide methods comprising any features, combinations of features and/or sub-combinations of features described herein or inferable therefrom.

Other aspects of the invention provide apparatus comprising any features, combinations of features and/or sub-combinations of features described herein or inferable therefrom.

Other aspects of the invention provide kits comprising any features, combinations of features and/or sub-combinations of features described herein or inferable therefrom.

In addition to the exemplary aspects and embodiments described above, further aspects and embodiments will become apparent by reference to the drawings and by study of the following detailed descriptions.

### BRIEF DESCRIPTION OF THE DRAWINGS

Exemplary embodiments are illustrated in referenced figures of the drawings. It is intended that the embodiments and figures disclosed herein are to be considered illustrative rather than restrictive.

FIG. 1 is a schematic diagram of an exemplary combinatorial printhead according to an embodiment of the invention.

FIG. 2 is a schematic diagram of another exemplary combinatorial printhead according to an embodiment of the invention.

FIG. 3 is a schematic diagram of an exemplary combinatorial printer according to an embodiment of the invention.

FIG. 4 is a block diagram of an exemplary method of combinatorial material screening according to an embodiment of the invention.

FIG. 5A is a schematic diagram of an exemplary substrate for combinatorial material screening according to an embodiment of the invention. FIG. 5B is a schematic diagram of another exemplary substrate for combinatorial material screening according to an embodiment of the invention.

FIG. 6 is a schematic diagram of another exemplary substrate for combinatorial material screening according to an embodiment of the invention.

FIG. 7A is a schematic diagram of an exemplary substrate for combinatorial material screening according to an embodiment of the invention. FIG. 7B is a schematic diagram of another exemplary substrate for combinatorial material screening according to an embodiment of the invention.

FIG. 8A is a conductivity map of deposited materials comprising poly(3,4-ethylenedioxythiophene)polystyrene sulfonate and dimethyl sulfoxide in various formulations. FIG. 8B is a conductivity map of deposited materials comprising poly(3,4-ethylenedioxythiophene)polystyrene sulfonate and dimethyl sulfoxide in various formulations.

FIG. 9A is a conductivity map of deposited materials comprising poly(3,4-ethylenedioxythiophene)polystyrene sulfonate and ethylene glycol in various formulations.

FIG. 9B is a conductivity map of deposited materials comprising poly(3,4-ethylenedioxythiophene)polystyrene sulfonate and ethylene glycol in various formulations.

FIG. 10A depicts a plot of conductivity as a function of composition for thin films of PEDOT:PSS and EG and PEDOT:PSS and DMSO. FIG. 10B depicts a plot of conductivity as a function of composition for thin films of PEDOT:PSS and EG and PEDOT:PSS and DMSO.

FIG. 11A is a morphology image of 100% (by volume) PEDOT:PSS. FIG. 11B is a phase image of 100% (by volume) PEDOT:PSS. FIG. 11C is a morphology image of a mixture of 90% (by volume) PEDOT:PSS and 10% (by volume) DMSO. FIG. 11D is a phase image of the mixture of 90% (by volume) PEDOT:PSS and 10% (by volume) DMSO. FIG. 11E is a morphology image of a mixture of 90% (by volume) PEDOT:PSS and 10% (by volume) EG. FIG. 11F is a phase image of the mixture of 90% (by volume) PEDOT:PSS and 10% (by volume) EG.

### DESCRIPTION

Throughout the following description specific details are set forth in order to provide a more thorough understanding to persons skilled in the art. However, well known elements may not have been shown or described in detail to avoid unnecessarily obscuring the disclosure. Accordingly, the description and drawings are to be regarded in an illustrative, rather than a restrictive, sense.

One aspect of the invention provides a printhead for controllably depositing combinatorial mixtures of a plurality of precursor materials (also referred to herein as precursors) in a thin film patterned on a substrate. A plurality of precursors may be controllably combined within the printhead prior to depositing the mixture onto the substrate to form a thin film in a desired pattern.

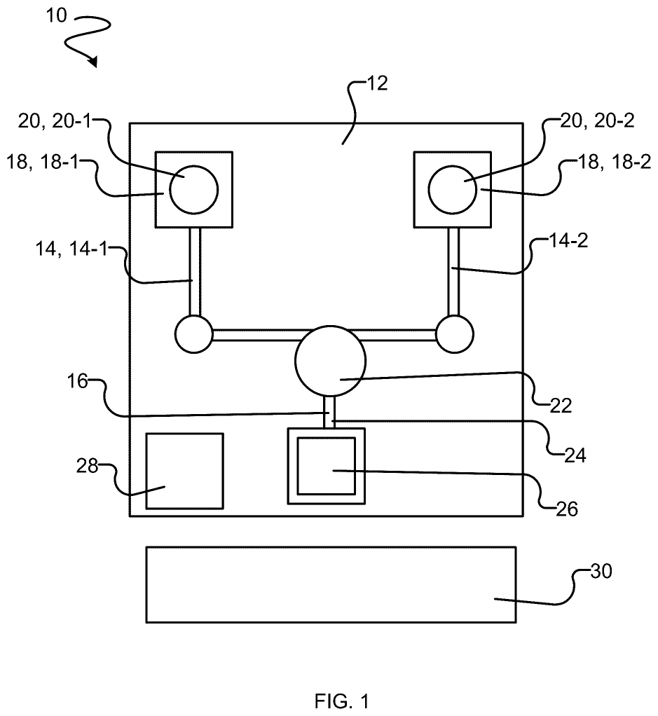

FIG. 1 is a schematic depiction of an exemplary printhead 10 according to one embodiment of the invention. Printhead 10 comprises a body 12. Body 12 may define a plurality of precursor channels 14, each fluidly connected to a mixing channel 16. For example, in the depicted embodiments, body 12 defines a first precursor channel 14-1 fluidly connected to mixing channel 16 to deliver a first precursor 20-1 to mixing channel 16 and a second precursor channel 14-2 fluidly connected to mixing channel 16 to deliver a second precursor 20-2 to mixing channel 16. Body 12 may be fabricated from any suitable material. In some embodiments, body 12 is fabricated from a polymeric material. In some embodiments, body 12 is fabricated from an elastomeric material (e.g. a silicone rubber compound).

Precursor channels 14 and/or mixing channel 16 may comprise microfluidic channels. In some embodiments one or more of precursor channels 14 have a cross-sectional area of between approximately 100 μm² and 250,000 μm². In some embodiments one or more of precursor channels 14 have a cross-sectional area of between approximately 100 μm² and 10,000 μm². In some embodiments, mixing channel 16 has a cross-sectional area of between approximately 200 μm² and 500,000 μm². In some embodiments, mixing channel 16 has a cross-sectional area of between approximately 200 μm² and 20,000 μm². In some embodiments, an internal cross-sectional area of mixing channel 16 is approximately equal to the sum of the internal cross-sectional areas of precursor channels 14 such that the rate of flow of precursors 20 is constant through precursor channels 14 and mixing channel 16. Precursor channels 14 and mixing channel 16 may have circular cross-sections and or cross-sections that are polygonal shaped.

In some embodiments, body 12 is fabricated by additive manufacturing (e.g. 3D printing). In some embodiments, body 12 is fabricated as a single monolithic structure. In other embodiments, body 12 is fabricated from two or more parts attached to each other (e.g. by bonding). In such embodiments, portions of channels (e.g. first precursor channel 14-1, second precursor channel 14-2 and mixing channel 16) may be formed into opposing sides of the two or more parts such that when the two or more parts are attached to one another, the portions of channels combine to define complete channels (e.g. first precursor channel 14-1, second precursor channel 14-2 and mixing channel 16). In some embodiments, body 12 is cast from a mold. In some embodiments, the mold is fabricated by additive manufacturing (e.g. 3D printing).

A pump 18 may be fluidly connected to each precursor channel 14. In the depicted embodiment, a first pump 18-1 is connected to first precursor channel 14-1 to force a first precursor 20-1 through first precursor channel 14-1 and into mixing channel 16. A second pump 18-2 is connected to second precursor channel 14-2 to force a second precursor 20-2 through second precursor channel 14-2 and into mixing channel 16. Pumps 18 may comprise any suitable type of pump for forcing first and second precursors 20-1, 20-2 through fist and second precursor channels 14-1, 14-2. In some embodiments, pumps 18 comprise flow controlled pumps or pressure controlled pumps. In some embodiments, pumps 18 comprise one or more syringe pumps, peristaltic pumps, self-priming micro pumps, piston pumps, etc. In some embodiments, gravity is employed instead of pumps and one or more valves may control a flow of each precursor 20 into the respective precursor channels 14. In some embodiments, pumps 18 comprise reservoir for storing precursor 20. In some embodiments, pumps 18 are connected or connectable to reservoirs for storing precursor 20.

Pumps 18 may be controlled in any suitable matter to force a desired amount of precursors 20 into precursor channels 14. In some embodiments, pumps 18 are controlled in an open loop manner by modulating drive signals of pumps 18 based at least in part on known calibration of pumps 18 and a desired volume or flow rate of precursors 20. In some embodiments, pumps 18 are controlled in a closed loop manner by modulating a drive signal of first pump 18-1 based at least in part on the desired volume or flow rate of precursors 20 and feedback from one or more sensors (e.g. volumetric sensors) measuring the volume or flow rate of precursors 20 through precursor channels 14. In some embodiments, pumps 18 have integrated closed loop feedback systems to achieve a desired volume or flow rate of precursors 20 consistently.

A mixer 22 may be provided to facilitate or encourage mixing of precursors 20 within mixing channel 16 to form a mixture 24. Mixer 22 may comprise any suitable mixer. In some embodiments, mixer 22 comprises one or more haptic motors, piezoelectric actuators, surface acoustic wave actuators, embedded passive structures, a diffusion mixer, a serpentine mixer, etc.

Mixer 22 may comprise a contact mixer such that mixer 22 or a portion thereof is located within mixing channel 16 and one or more parts of mixer (e.g. an impeller) contact precursors 20 to thereby mix precursors 20.

Mixer 22 may comprise a non-contact mixer such that mixer 22 does not contact precursors 20. For example, mixer 22 may comprise a vibrator or agitator (e.g. a haptic motor) attached to body 12 in a location proximate to mixing channel 16 (e.g. above, below, beside, etc.), such that mixer 22 causes the contents of mixing channel 16 to vibrate when mixer 22 is actuated to thereby facilitate or encourage mixing of the contents of mixing channel 16 (e.g. first and second precursors 20-1, 20-2). In some embodiments, mixing channel 16 travels through mixer 22. By employing a non-contact mixer 22, a length of mixing channel 16 may be reduced (e.g. as compared to embodiments where precursors 20 are allowed to passively mix within mixing channel 16). Reducing the length of mixing channel may in turn reduce the volume of wasted precursor 20 when using printhead 10. This efficient use of precursor 20 is particularly advantageous when working with low-yield, research-grade and/or potentially expensive precursor materials. A non-contact mixer 22 may not impinge on mixing channel 16 thereby allowing mixing channel 16 to have a consistent cross-sectional area along its length. A non-contact mixer may reduce a chance of contamination of precursors 20 as they travel through mixing channel 16. A vibrating or agitating non-contact mixer 22 may be compatible with a wide range of fluid properties (e.g. viscosities, diffusion properties, etc.) thereby increasing the range of use of printhead 10. A vibrating or agitating non-contact mixer 22 may also decrease mixing time of precursors 20 within mixing channel 16 (e.g. as compared to passive mixing) and may thereby allow for increased flow rates of precursors 20 through mixing channel 16. Further, a vibrating or agitating non-contact mixer 22 may facilitate fabrication of printhead 10 (e.g. as installing a vibrating or agitating non-contact mixer 22 does not require micro- or nano-scale fabrication).

Mixing channel 16 may be fluidly connected to a dispenser 26 for controllably depositing mixture 22 onto a substrate 30 or other suitable target media which may be referred to herein as substrate 30 without loss of generality. Dispenser 26 may comprise any suitable dispenser for controllably depositing mixture 22 onto substrate 30. For example, dispenser 26 may comprise a bubble jet dispenser, an inkjet dispenser, a drop-on-demand dispenser, etc. In some embodiments, dispenser 26 comprises a thermal-triggered drop-on-demand dispenser or a piezoelectric triggered drop-on-demand dispenser. Drop-on-demand dispensers, such as those mentioned above, allow for tight control of the shape and thickness of thin films of mixture 22 deposited onto substrate 30 while minimizing volume usage of mixture 22. This tight control and efficiency is particularly advantageous when working with low-yield, research-grade and potentially expensive precursor materials.

One or more controllers 28 may be provided to control actuation of one or more of first and second pumps 18-1, 18-2, mixer 22 and dispenser 26. Signal amplifiers and other control circuitry (not expressly illustrated) may be provided to actuate pumps 18, mixer 22 and/or dispenser 26.

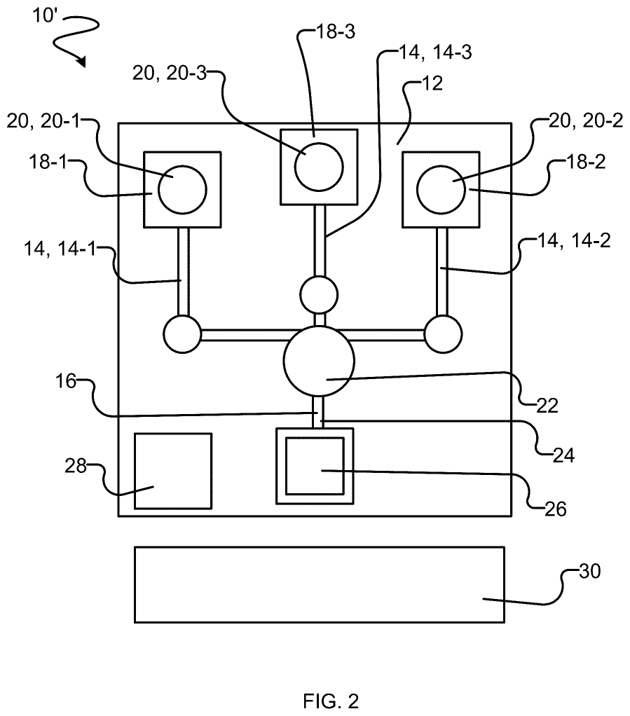

While printhead 10 is depicted and described as having only two precursor channels 14, it should be understood that printhead 10 could comprise more than two precursor channels 14 to allow for mixing of more than two precursors 20. For example, FIG. 2 is a schematic depiction of an exemplary printhead 10′ according to an exemplary embodiment of the invention. Printhead 10′ is substantially similar to printhead 10, except that printhead 10′ comprises a third precursor channel 14-3 and a corresponding third pump 18-3 for forcing a third precursor 20-3 through third channel 14-2 into mixing channel 16.

In some embodiments, printhead 10 is modular. For example, in some embodiments, one or more of pumps 18, mixer 22 and dispenser 26 can be moved between different bodies 12 where the different bodies have for example, different numbers of precursor channels 14, different lengths of mixing channel 16, different cross-sectional areas of one or more of precursor channels 14 and mixing channel 16 as desired to accommodate, for example, different precursors 20. Similarly, pumps 18, mixer 22 and/or dispenser 26 may be replaced with different types of pumps, mixers and/or dispensers as desired to accommodate, for example, different precursors 20. Such modularity may also facilitate repair of printhead 10. Such modularity may also allow for the addition of further modules such as sensors, heaters, coolers, etc.

Another aspect of the invention provides a combinatorial printer for controllably depositing combinatorial mixtures of a plurality of precursors in a thin film on a substrate. The combinatorial printer may comprise a combinatorial printhead (e.g. printhead 10, 10′ or any other printhead described herein). The printhead may be mounted to a linear actuator for controllable z-direction movement of the printhead. A stage is provided to support a substrate. The stage may be actuated by one or more linear actuators for controllable x- and y-direction movement of the stage, where the x-direction and y-direction are each orthogonal to one another and to the z-direction. By controlling z-direction movement of the printhead, x- and y-direction movement of the substrate and fluid ejection from the printhead dispenser, the mixture produced by the printhead may be deposited onto the substrate in a desired pattern. Additionally or alternatively, the printhead may be stationary while the stage is controllably moveable in the x-, y- and z-directions or the stage may be stationary while the printhead is controllably moveable in the x-, y- and z-directions. In some embodiments, the printhead and/or stage are controllable in the x- and y-directions but are fixed relative to each other in the z-direction.

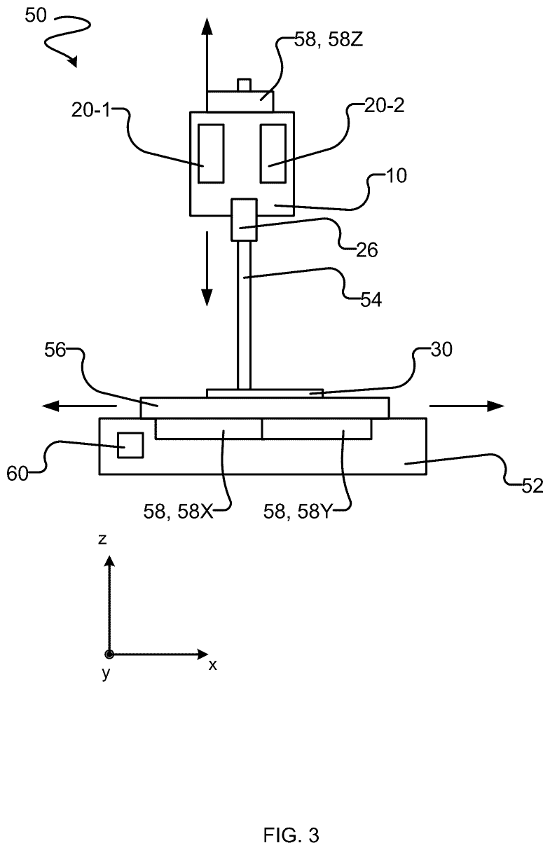

FIG. 3 is a schematic depiction of an exemplary combinatorial printer 50 (also referred to herein as printer 50) according to an embodiment of the invention. For convenience, printer 50 is depicted and described herein as employing printhead 10. However, it should be understood that this is not mandatory. Printer 50 may employ printhead 10, printhead 10′, and/or any other printhead described or depicted herein. In some embodiments, printer 50 employs one or more printheads not described herein.

Printer 50 comprises a base 52. Base 52 may comprise or support a stage 56. A substrate 30 is supportable by stage 56. One or more actuators may be controlled to cause movement of stage 56 relative to base 52. For example, an x-direction actuator 58X may be controlled to cause x-direction movement of stage 56 and a y-direction actuator 58Y may be controlled to cause y-direction movement of stage 56.

A column 54 may extend from base 52. Column 54 may support a printhead 10. An actuator may be employed to cause z-direction movement of printhead 10 relative to base 52. For example, a z-direction actuator 58Z may be controlled to cause z-direction movement of printhead 10 relative to base 52 (and relative to stage 56).

The x-, y- and z-direction actuators 58X, 58Y, 58Z (collectively referred to herein as actuators 58) may comprise any suitable type(s) of actuators. For example, one or more of actuators 58 may comprise linear actuators, rotary actuators hydraulic actuators, pneumatic actuators, electrical actuators, thermal actuators, magnetic actuators, mechanical actuators, etc. In some embodiments, one or more of actuators 58 comprise linear actuators (e.g. hydraulic linear actuators, pneumatic linear actuators, piezoelectric linear actuators and/or electro-mechanical linear actuators).

In some embodiments, one or more controllers 60 are provided to control actuation of linear actuators 58. In some embodiments, controller 28 of printhead 10 are employed to control actuation of linear actuators 58.

In some embodiments, stage 56 is stationary and printhead 10 is moveable in the x-, y- and z-directions. For example, in some embodiments, printer 50 is a gantry-type printer. In some embodiments, printhead 10 is stationary and stage 56 is moveable in the x-, y- and z-directions.

Another aspect of the invention provides a method for combinatorial material screening and discovery. The method may allow for depositing a number, n, of combinatorial mixtures of a plurality of precursors in thin films onto a substrate for testing. While the method may employ a plurality of precursors from which mixtures may be formed prior to depositing onto a substrate, for ease of explanation, the methods described and depicted herein may be described and depicted as using only two precursors. It should be understood that the same methods would apply for mixing more than two precursors.

In some embodiments, the method comprises causing a first volume of a first precursor to travel through a first precursor channel into a mixing channel and causing a second volume of a second precursor to travel through a second precursor channel into the mixing channel. The first and second volumes of the first and second precursors may be mixed in the mixing channel to form a first mixture. The first mixture may be deposited onto a substrate into a first pattern (e.g. in a first thin film pattern). A third volume of the first precursor may be caused to travel through the first precursor channel into the mixing channel and a fourth volume of the second precursor may be caused to travel through the second precursor channel into the mixing channel. The third and fourth volumes of the first and second precursors may be mixed in the mixing channel to form a second mixture. The second mixture may be deposited onto the substrate in a second pattern (e.g. in a second thin film pattern). One or more additional mixtures of the first and second precursors may be mixed and deposited in a similar manner to the first and second mixtures. One or more characteristics of the thin films (e.g. the first thin film, the second thin film, etc.) may then be measured and/or compared.

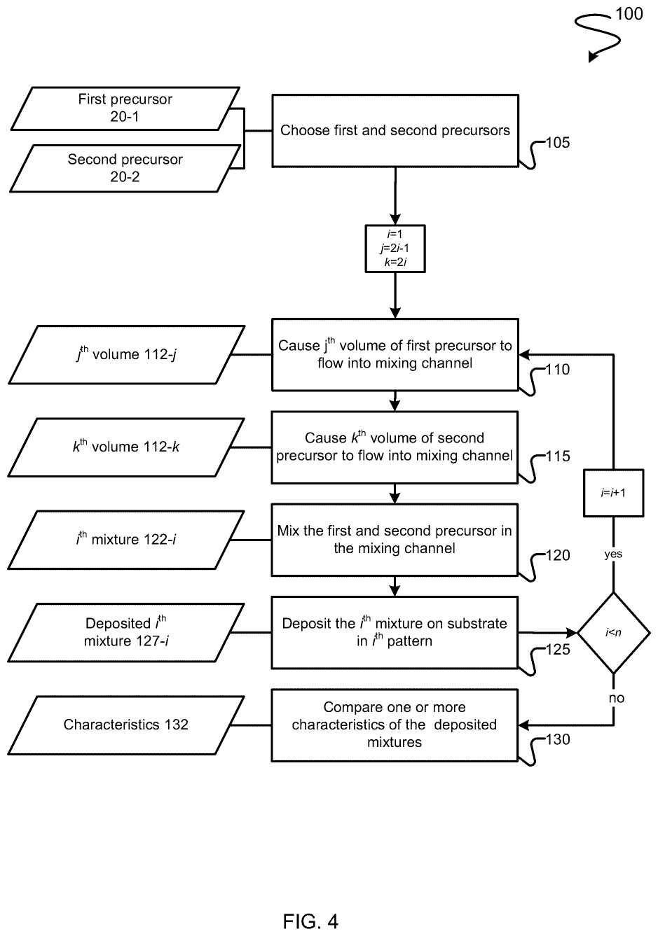

FIG. 4 depicts an exemplary method 100 for combinatorial material screening according to an embodiment of the invention. For convenience, method 100 is depicted and described herein as employing printhead 10 and combinatorial printer 50. However, it should be understood that this is not mandatory. Method 100 may employ printhead 10, printhead 10′, combinatorial printer 50 and/or any other printhead or combinatorial printer described or depicted herein. In some embodiments, method 100 employs one or more printheads and/or printers not described or depicted herein.

Method 100 may start at block 105 with choosing two or more precursors 20 (e.g. a first precursor 20-1 and a second precursor 20-2). Precursors 20 may comprise any solution or stabilized dispersion of, for example, inorganic polymers, organic polymers, inorganic compounds, organometallic compounds, stoichiometric alloys (and/or components thereof), biomaterials, carbon allotropes, quantum dots, other novel chemical systems, etc. Precursors 20 may comprise additives such as organic surfactants, inorganic surfactants, co-solvents, binders, diluents, etc. In some embodiments, precursors 20 are chosen such that an eventual mixture 22 thereof has an Ohnesorge number between approximately 0.1 and 1. Precursors 20 may be chosen based at least in part on one or more of viscosity, surface tension, suitability for printing (e.g. by inkjet printing, drop on demand printing, etc.)

In some embodiments, first precursor 20-1 has one or more characteristics of interest wherein at least one of the characteristics may be characterized by the quantity, Q. Q may be a measure of any suitable characteristic such as, but not limited to, electrical characteristics, physical characteristics, practical characteristics, magnetic characteristics, ferroelectric characteristics, photovoltaic characteristics, thermoelectric characteristics, optical characteristics, etc. Example electrical characteristics include conductivity, resistance, etc. Example physical characteristics include energy required to set, degree of cross-linking, time to set, polymerization, Young's Modulus, morphology, UV light absorbance, surface roughness, surface hardness, viscosity, surface tension, Ohnesorge number, etc. Practical characteristics include suitability for printing (e.g. suitability for depositing by thermal triggered drop-on-demand printing, suitability for depositing by piezoelectric triggered drop-on-demand printing, suitability for depositing by inkjet printing), suitability for patterning, interaction with substrate 30, etc. In some embodiments, second precursor 20-2 comprises an additive which is used to tune Q through a chemical or physical transformation. For example, second precursor 20-2 may comprise a surfactant (e.g. to improve film adhesion on certain classes of substrates).

At block 110, a j^{th} volume 112-j of first precursor 20-1 is caused to flow into mixing channel 16 through first precursor channel 14-1, where j=2i−1 and i is an integer number representing the mixture number. For example, for the first occurrence of block 110, i=1 and a first volume 112-1 of first precursor 20-1 is caused to flow into mixing channel 16 through first precursor channel 14-1. Likewise, for the second occurrence of block 110, i=2 and a third volume 112-3 of first precursor 20-1 is caused to flow into mixing channel 16 through first precursor channel 14-1.

The j^{th} volume 112-j of first precursor 20-1 may be caused to flow into mixing channel 16 through first precursor channel 14-1 by actuation of first pump 18-1. In some embodiments, a flow rate of first precursor 20-1 from first pump 18-1 is controlled during a period of time to deliver j^{th} volume 112-j into mixing channel 16 at block 110. In some embodiments the flow rate is between approximately 0.1 μl/min and 10.5 ml/min. As discussed above, flow rate of first precursor 20-1 may controlled in an open loop manner (e.g. by modulating a drive signal of first pump 18-1 based on known calibration of first pump 18-1) or a closed loop manner (e.g. by modulating a drive signal of first pump 18-1 based on feedback from one or more sensors.)

At block 115, a k^{th} volume 112-k of second precursor 20-2 is caused to flow into mixing channel 16 through second precursor channel 14-2, where k=2i. For example, for the first occurrence of block 115, i=1 and a second volume 112-2 of second precursor 20-2 is caused to flow into mixing channel 16 through second precursor channel 14-2. Likewise, for the second occurrence of block 115, i=2 and a fourth volume 112-4 of second precursor 20-2 is caused to flow into mixing channel 16 through second precursor channel 14-2.

The k^{th} volume 112-k of second precursor 20-2 may be caused to flow into mixing channel 16 through second precursor channel 14-2 by actuation of second pump 18-2. In some embodiments, a flow rate of second precursor 20-2 from second pump 18-2 is controlled during a period of time to deliver k^{th} volume 112-k into mixing channel 16 at block 115. In some embodiments the flow rate is between approximately 0.1 μl/min and 10.5 ml/min. As discussed above, flow rate of second precursor 20-2 may controlled in an open loop manner (e.g. by modulating a drive signal of second pump 18-2 based on known calibration of second pump 18-2) or a closed loop manner (e.g. by modulating a drive signal of second pump 18-2 based on feedback from one or more sensors.)

The j^{th} and k^{th} volumes 112-j, 112-k may be chosen to achieve a desired ratio of first precursor 20-1 to second precursor 20-2. The desired ratio may be any ratio between approximately 0-100% (by volume) of first precursor 20-1 to 0-100% (by volume) of second precursor 20-2, as discussed further herein.

At block 120, j^{th} and k^{th} volumes 112-j, 112-k of the first and second precursors 20-1, 20-2 respectively are mixed in mixing channel 16 to form a first mixture 122-i. For example, for the first occurrence of block 120, where i=1, first and second volumes 112-1, 112-2 of the first and second precursors 20-1, 20-2 respectively are mixed in mixing channel 16 to form a first mixture 122-1. In some embodiments, mixing of first and second precursors 20-1, 20-2 within mixing channel 16 occurs passively (e.g. without substantial added energy, agitation, vibration, etc.) as first and second precursors 20-1, 20-2 flow through mixing channel 16. In some embodiments, the contents of mixing channel (e.g. first and second precursors 20-1, 20-2) are actively mixed (e.g. through added energy, agitation, vibration, etc.). For example, in some embodiments, mixer 22 agitates the contents of mixing channel 16.

The length of time during which first and second precursors 20-1, 20-2 are mixed at block 120 may be dependent on the composition of one or both of first and second precursors 20-1, 20-2, the rate of flow of first and second precursors 20-1, 20-2, the length of mixing channel 16, the cross-sectional area of mixing channel 16, the temperature of precursors 20, the amount of energy added at block 120 (e.g. the intensity of agitation, vibration, etc.), etc. The amount of energy added at block 120 (e.g. the intensity of agitation, vibration, etc.) and whether energy is added at block 120 (e.g. passive or active mixing) may also be dependent on the composition of one or both of first and second precursors 20-1, 20-2, the rate of flow of first and second precursors 20-1, 20-2, the length of mixing channel 16, the cross-sectional area of mixing channel 16, the temperature of precursors 20, etc.

At block 125, the i^{th} mixture 122-i is deposited onto a substrate 30 in an P pattern 124-i to form an i^{th} thin film 127-i. For example, for the first occurrence of block 125, where i=1, first mixture 122-1 is deposited onto substrate 30 in a first pattern 124-1 to form first thin film 127-1. For the second occurrence of block 125, where i=2, second mixture 122-2 is deposited onto substrate 30 in a second pattern 124-2 to form second thin film 127-2.

For convenience, patterns described and/or depicted herein (e.g. i^{th} pattern 124-i, first pattern 124-1, etc.) may be referred to collectively as patterns 124 or individually as a pattern 124; thin films 127 described and/or depicted herein (e.g. i^{th} thin film 127-i, first thin film 127-1, etc.) may be referred to collectively as thin films 127 or individually as a thin film 127; and mixtures described and/or depicted herein (e.g. i^{th} mixture 122-i, first mixture 122-1, etc.) may be referred to collectively as mixtures 122 or individually as a mixture 122.

Each mixture 122 may be deposited onto substrate 30 by dispenser 26 to form a thin film 127. In some embodiments, mixtures 122 are deposited onto substrate 30 by one or more of bubble jet printing, inkjet printing, drop-on-demand printing (e.g. thermal-triggered drop-on-demand printing or piezoelectric triggered drop-on-demand printing), etc. For example, in some embodiments, mixture 122 is deposited onto substrate 30 by ejecting mixture 122 through a nozzle (e.g. dispenser 26) and patterning the ejected mixture onto substrate 30 with magnetic fields. Such magnetic fields may be generated by components of dispenser 26.

Substrate 30 may comprise any suitable substrate or other suitable target media which may be referred to herein as substrate 30 without loss of generality. The composition of substrate 30 may be dependent on the composition of precursors 20. In some embodiments, substrate 30 comprises glass, plastic, paper, wood, metal etc. In some embodiments, substrate 30 comprises an electrically insulating material. In some embodiments, substrate 30 comprises a glass plate.

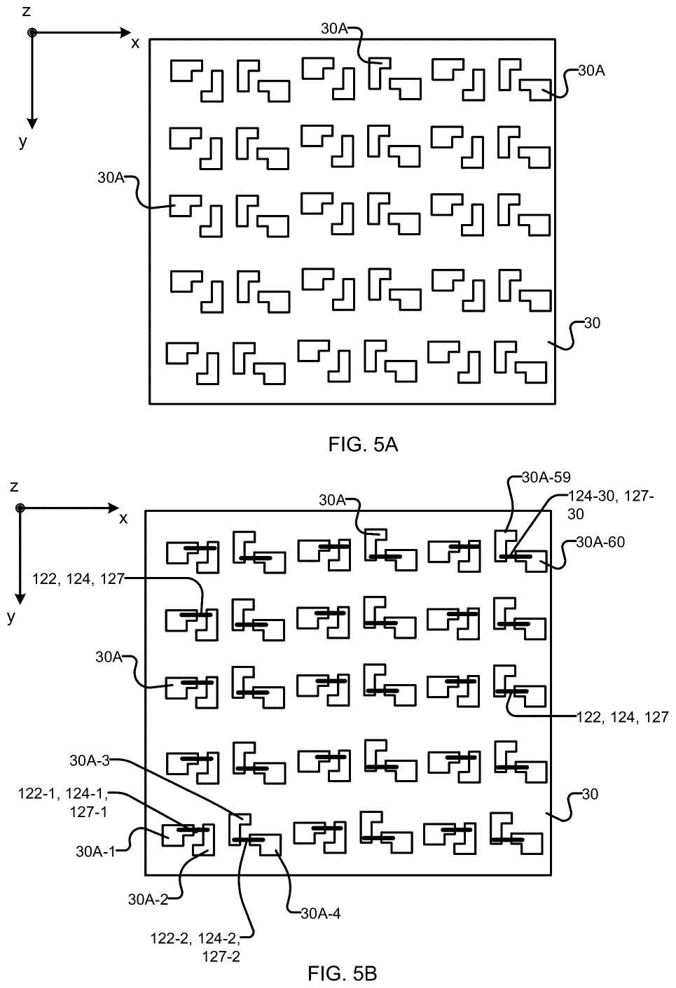

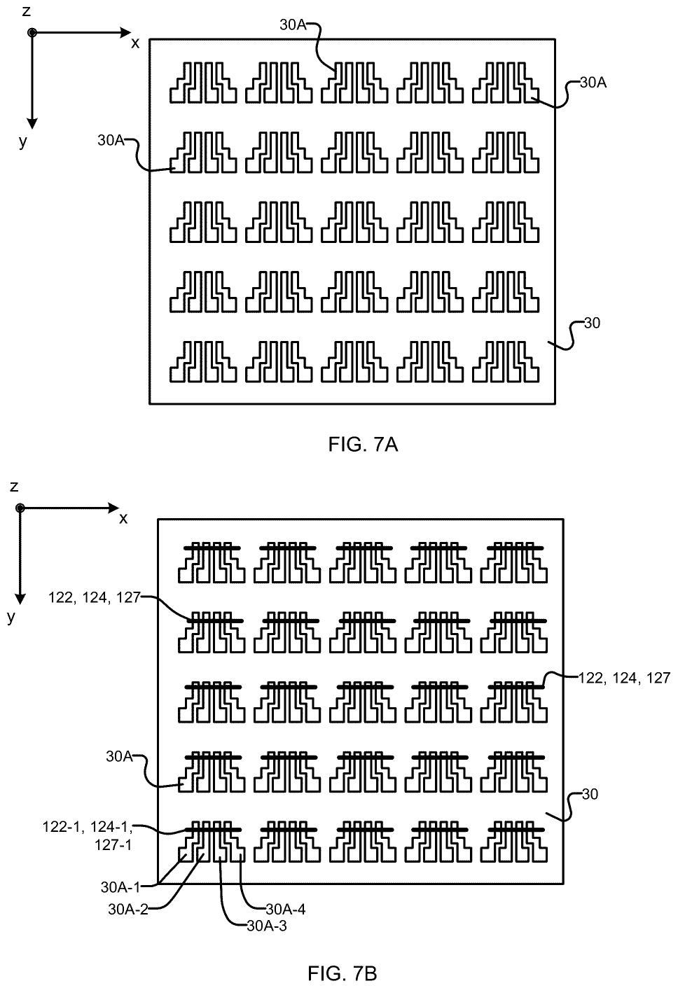

In some embodiments, substrate 30 is patterned with two or more electrodes 30A. For example, FIG. 5A depicts an exemplary substrate 30 having a plurality of electrodes 30A patterned thereon. As another example, FIG. 7A depicts another exemplary substrate 30 having a plurality of electrodes 30A patterned thereon. Electrodes 30A may comprise, for example, silver, gold, platinum, titanium, iridium, palladium, aluminium, copper, nickel, chromium-gold, nickel-chromium, platinum-palladium, etc. Electrodes 30A may be applied by various deposition methods including, but not limited to, solution processing (e.g. screen printing, stencil printing, etc.), physical deposition (electron-beam evaporation, sputtering etc.), chemical deposition, vapor deposition, etc. Depositing mixture 122 on substrate 30 in pattern 124 may comprise depositing mixture 122 in pattern 124 on at least a portion of one or more electrodes 30A. For example, FIGS. 5B and 7C depict deposited thin films 127 in patterns 124 that are at least in part on one or more electrodes 30A.

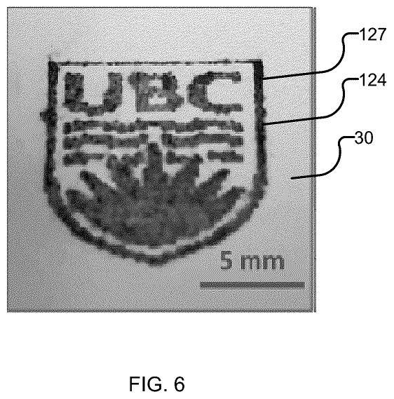

At block 125, each mixture 122 may deposited on substrate 30 in any suitable pattern 124. In some embodiments, depositing a mixture 122 on substrate 30 at block 125 comprises depositing a mixture 122 on top of (in whole or in part) a previously deposited thin film 127 to form multiple layers of thin film 127, each potentially having a different composition and/or characteristic(s). Depositing mixture 122 on substrate 30 in pattern 124 may comprise controlling x-, y- and/or z-direction movement of printhead 10 relative to stage 56 (and/or controlling x-, y- and/or z-direction movement of stage 56 relative to printhead 10) to deposit mixture 122 on substrate 30 directly in pattern 124 (e.g. without masking or etching steps). Patterns 124 may vary in the x-, y- and/or z-directions. X-, y- and z-direction variation of patterns 124 may be achieved by control of printhead 10 and or stage 56. Z-direction variation of patterns 124 may alternatively or additionally be controlled by depositing successive layers of mixtures 122 on top of one another thereby layering successive patterns 124 and creating variation in the z-direction (e.g. variation of thin film composition in the z-direction). FIG. 6 depicts a first exemplary pattern 124-1 of a first thin film 127-1 deposited according to method 100 and shaped in the crest of the University of British Columbia.

In some embodiments, patterns 124 are chosen to facilitate testing of one or more characteristics of the respective thin film 127. For example, FIG. 5B depicts a first pattern 124-1 shaped to connect a first electrode 30A-1 to a second electrode 30A-2. The FIG. 5B pattern 124-1 facilitates testing of electrical characteristics (e.g. resistance, conductivity, etc.) of first thin film 127-1 at block 130 by taking measurements across first and second electrodes 30A-1, 30A-2, as discussed further herein. As another example, FIG. 7B depicts a first pattern 124-1 shaped to connect across, first electrode 30A-1, second electrode 30A-2, third electrode 30A-3 and fourth electrode 30A-4. The FIG. 7B pattern 124-1 facilitates testing of electrical characteristics (e.g. resistance, conductivity, etc.) of first thin film 127-1 at block 130 by facilitating taking measurements across any combination of first, second, third and fourth electrodes 30A-1, 30A-2, 30A-3, 30A-4 thereby providing multiple possible measurements for each thin film 127.

After block 125, method 100 may continue to block 130 if is greater or equal to the total number of mixtures to be deposited, n. However, if i is less than n, then i is increased by one and method 100 returns to block 110.

In some embodiments, precursor channels 14 and/or mixing channel 16 are flushed between block 125 and returning to block 110 to ensure that no precursor 20 left from a previous occurrence of blocks 110 to 125 affects a next occurrence of blocks 110 to 125. In some embodiments, precursor channels 14 and/or mixing channel 16 are flushed with a solvent such as, for example, de-ionized water, ethanol, isopropanol, etc. In some embodiments, precursor channels 14, mixing channel 16 and/or dispenser 26 are flushed with precursor 20 to remove blockages.

For illustrative purposes, a second occurrence of blocks 110 through 125 is described as follows. At the second occurrence of block 110, a third volume 112-3 of first precursor 20-1 is caused to flow through first precursor channel 14-1 into mixing channel 16. At the second occurrence of block 115, a fourth volume 112-4 of second precursor 20-2 is caused to flow through second precursor channel 14-2 into mixing channel 16. At the second occurrence of block 120, the third and fourth volumes 112-3, 112-4 of the first and second precursors 20-1, 20-2 respectively are mixed in mixing channel 16 to form a second mixture 122-2. At the second occurrence of block 125, the second mixture 122-2 is deposited onto the substrate 30 in a second pattern 124-2 (e.g. deposited directly in second pattern 124-2 on substrate 30 without additional steps such as etching or masking) to form second thin film 127-2.

In some embodiments, each mixture 122 is deposited onto the same substrate (e.g. second mixture 122-2 is deposited onto the same substrate 30 as first mixture 122-1). This is not mandatory. In some embodiments, one or more mixtures 122 are deposited onto different substrates 30 during method 100.

Second mixture 122-2 may be deposited in any second pattern 124-2. As with first pattern 124-1, second pattern 124-2 may be chosen to facilitate testing of one or more characteristics of second thin film 127-2. In some embodiments, second pattern 124-2 is substantially similar to first pattern 124-1. In some embodiments, second pattern 124-2 is substantially similar to first pattern 124-1, but is located at a different location on substrate 30. For example, FIG. 5B depicts a second pattern 124-2 shaped to connect a third electrode 30A-3 to a fourth electrode 30A-4. The FIG. 5B pattern 124-2 facilitates testing of electrical characteristics (e.g. resistance, conductivity, etc.) of first thin film 127-2 at block 130, as discussed further herein.

In some embodiments, patterns 124 is deposited in successive iterations of block 125 differ in scale (e.g. one or more of x-direction length, y-direction width and z-direction thickness). In this way, the effect of x-direction length, y-direction width and/or z-direction thickness can be examined, as discussed further herein.

FIG. 5B depicts an exemplary substrate 30 having n=30 thin films 127 made from first and second precursors 20-1, 20-2. FIG. 5B depicts a first thin film 127-1 in a first pattern 124-1 connecting first and second electrodes 30A-1, 3-A-2, a second thin film 127-2 in a second pattern 124-2 connecting third and fourth electrodes 30A-3, 30A-4 and so on up to and including a thirtieth thin film 127-30 in a thirtieth pattern 124-30 connecting 59^{th} and 60^{th} electrodes 30A-59, 30A-60.

One or more of mixtures 122 deposited to form the 30 thin films 127 may comprise a different ratio of first precursor 20-1 to second precursor 20-2. This may facilitate determination of the effect of formulation of mixtures 122 on one or more characteristics of thin films 127 at block 130.

Two or more thin films 127 of the 30 thin films 127 may comprise the same ratio of first precursor 20-1 to second precursor 20-2 printed in the same pattern 124. This may facilitate ensuring that test results at block 30 are consistent and repeatable.

Two or more thin films 127 of the 30 thin films 127 may comprise the same ratio of first precursor 20-1 to second precursor 20-2 printed in different patterns 124. For example, their respective patterns 124 may differ in shape and/or size (e.g. x-direction length, y-direction width and/or z-direction thickness). This may facilitate determination of the effect of patterning of thin films 127 on one or more characteristics of thin films 127 at block 130.

In some embodiments, thin films 127 are allowed to set (e.g. dry, solidify, cure etc.) as may be needed prior to block 130. In some embodiments setting is assisted by application of heat and/or light (e.g. UV light) to thin films 127. In some embodiments, setting is allowed to occur passively (e.g. by the passage of time without added heat or light). In some embodiments, substrate 30 with thin films 127 is placed in an oven (e.g. a vacuum oven) to set. In some embodiments, the oven is set to a temperature of between approximately 25° C. and 390° C. In some embodiments, the oven is set to a temperature of approximately 60° C.

At block 130, one or more characteristics 132 of each thin film 127 (e.g. first thin film 127-1, second thin film 127-2, i^{th} thin film 127-i, etc.) are compared. For example, in some embodiments, the quantity, Q, is be measured and compared at block 130.

Characteristics 132 may comprise any suitable characteristics such as, but not limited to, electrical characteristics, physical characteristics, practical characteristics, magnetic characteristics, ferroelectric characteristics, photovoltaic characteristics, thermoelectric characteristics, etc. Example electrical characteristics include conductivity, resistance, etc. Example physical characteristics include, degree of cross-linking, polymerization, Young's Modulus, morphology, UV light absorbance, surface roughness, surface hardness, viscosity, surface tension, Ohnesorge number, etc. Practical characteristics include energy required to set, time required to set, suitability for printing (e.g. suitability for depositing by thermal triggered drop-on-demand printing, suitability for depositing by piezoelectric triggered drop-on-demand printing, suitability for depositing by inkjet printing), suitability for patterning, etc.

Characteristics 132 may be measured and compared using any suitable technique(s).

For example, where a thin film 127 is patterned between two electrodes 30A on a substrate (e.g. first thin film 127-1 patterned between first and second electrodes 30A-1, 30A-2) an electrical signal (e.g. known voltage) may be applied across the electrodes 30A (e.g. across first and second electrodes 30A-1, 30A-2) and the resistance of the deposited mixture (e.g. first thin film 127-1) may be determined (e.g. by measuring the current across first and second electrodes 30A-1, 30A-2 and subsequently determining resistance based at least in part on the measured current and known voltage). Further, by also measuring the x-direction length, y-direction width and z-direction thickness of a thin film 127 (e.g. first thin film 127-1), the resistivity and conductivity of the thin film 127 (e.g. first thin film 127-1) may be determined.

As another example, surface roughness of a thin film 127 may be measured with a roughness meter (e.g. by tracing a probe of a contact-type roughness meter over thin film 127 or by projecting a laser of a non-contact-type roughness meter along thin film 127), surface profilometry (optical or stylus-based), scanning electron microscopy (e.g. with a scanning tunneling microscope, atomic force microscope, etc.).

As another example, surface hardness of a thin film 127 may be measured using an indentation test (e.g. the Brinell test, the Vicker's Diamond test and the Rockwell test), nano-indentation test, etc. Young's modulus may also be obtained by determining the slope of the stress-strain curve obtained from such an indentation test or nano-indentation test. Alternatively, Young's modulus may be obtained with an atomic force microscope.

Method 100 may be used repeatedly as part of an iterative process. For example, method 100 may be used to fabricate and deposit mixtures 122 having a wide variety of formulations at a relatively low compositional resolution (e.g. a ratio of the number of different formulations relative to the total magnitude of the range of combinations represented is smaller). If block 130 demonstrates any notable trends (e.g. maxima or minima) of one or more characteristics relative to the formulation in a particular range of formulations, method 100 may be repeated to fabricate and deposit mixtures 122 having a relatively higher compositional resolution (e.g. a ratio of the number of different formulations relative to the total magnitude of the range of combinations represented is higher) within the particular identified range of formulations. Method 100 may be repeated iteratively at higher and higher compositional resolutions as desired (e.g. until an optimal formulation is achieved).

In some embodiments, each block of method 100 occurs serially with no temporal overlap of blocks. This is not mandatory. In other embodiments, one or more blocks (or portions thereof) of method 100 may occur concurrently. For example, blocks 110, 115 and 120 may occur in whole or in part at the same time. As another example, where i<n and method 100 continues form block 125 to block 110, block 110 may restart before block 125 has completed.

### Experimental Validation

To demonstrate the effectiveness of printhead 10, printer 50 and method 100, the inventors conducted a first experiment using a first combination of first precursor 20-1 of poly(3,4-ethylenedioxythiophene)polystyrene sulfonate (“PEDOT:PSS”) and a second precursor 20-2 of dimethyl sulfoxide (“DMSO”) and a second experiment using a second combination of PEDOT:PSS as a first precursor 20-1 and ethylene glycol (“EG”) as a second precursor 20-2. PEDOT:PSS is an electroactive polymer with multidisciplinary applications. DMSO and EG were chosen as the second precursors 20-2 due to their known conductivity modulating effect on first precursor 20-1 PEDOT:PSS.

For each combination, the inventors chose to deposit linear patterns 24 of mixtures 22 between adjacent silver electrodes on a glass substrate 30 (e.g. similar to patterns 24 of FIG. 5B) starting with 100% (by volume) PEDOT:PSS and down to 50% (by volume) PEDOT:PSS in steps of 10% (by volume) according to method 100. Five mixtures 22 were deposited for each composition for a total of 30 thin films 127 of PEDOT:PSS and DMSO and 30 thin films 127 of PEDOT:PSS and EG.

The thin films 127 were then dried in an oven at 60° C. for 5 min and then cooled to 25° C. before being individually characterized.

Resistance measurements for each of the thin films 127 were obtained. Thin films 127 were measured in the x-, y- and z-directions. The z-direction measurements were obtained at three different points along the x-direction length of each thin film 127 and averaged to accommodate variations due to surface roughness. Conductivity of each thin film 127 was then determined based at least in part on the obtained resistance measurements and the x-, y- and z-direction measurements.

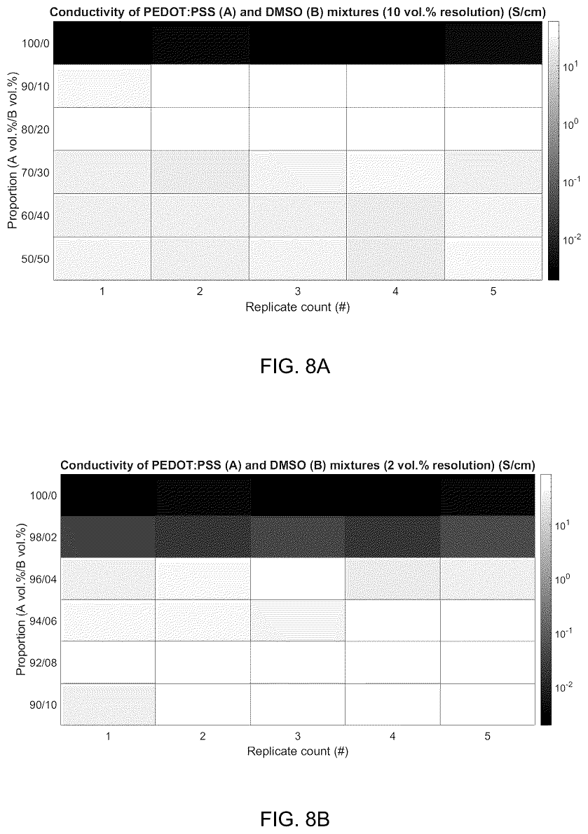

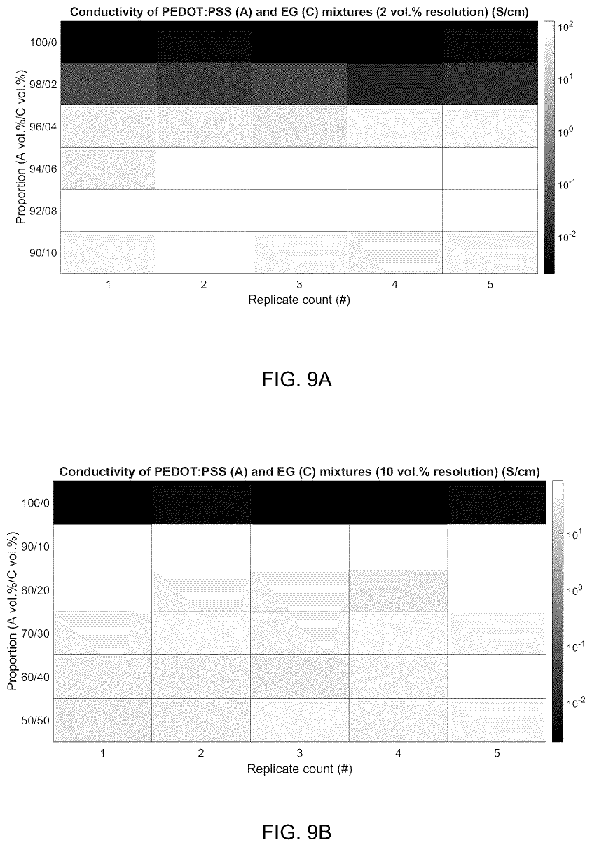

FIG. 8A depicts a conductivity map of each of the 30 thin films 127 of the first combination from 100% (by volume) PEDOT:PSS and 0% (by volume) DMSO down to 50% (by volume) PEDOT:PSS and 50% (by volume) DMSO in steps of 10% (by volume). FIG. 9A depicts a conductivity map of each of the 30 thin films 127 of the second combination from 100% (by volume) PEDOT:PSS and 0% (by volume) EG down to 50% (by volume) PEDOT:PSS and 50% (by volume) EG in steps of 10% (by volume).

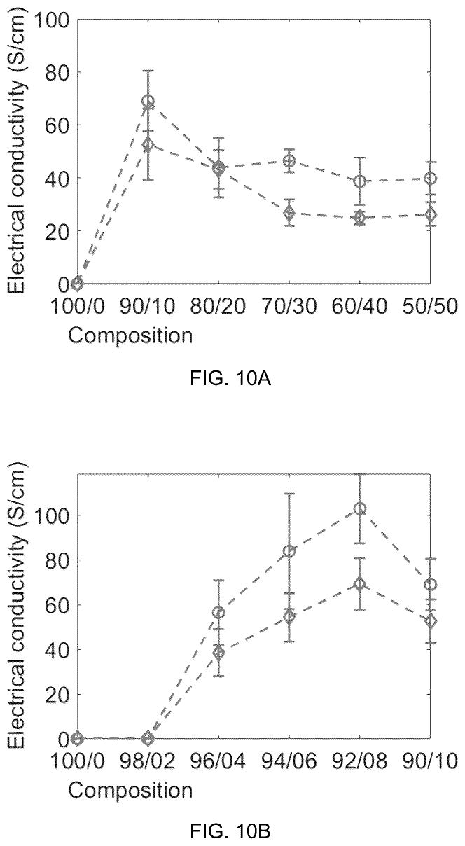

FIG. 10A depicts a plot of conductivity as a function of composition for each of the 30 thin films 127 of the first combination from 100% (by volume) PEDOT:PSS and 0% (by volume) EG down to 90% (by volume) PEDOT:PSS and 10% (by volume) EG in steps of 2% (by volume) as represented by the diamond data points. FIG. 10B depicts a plot of conductivity as a function of composition for each of the 30 thin films 127 of the second combination from 100% (by volume) PEDOT:PSS and 0% (by volume) EG down to 90% (by volume) PEDOT:PSS and 10% (by volume) EG in steps of 2% (by volume) as represented by the diamond data points.

Due to the significant difference in conductivity at 100% (by volume) PEDOT:PSS as compared to at 90% (by volume) PEDOT:PSS, the inventors then chose, for each combination, to deposit linear patterns 24 of mixtures 22 between adjacent silver electrodes on a glass substrate 30 (e.g. similar to patterns 24 of FIG. 5B) starting with 100% (by volume) PEDOT:PSS and down to 90% (by volume) PEDOT:PSS in steps of 2% (by volume) according to method 100. Five mixtures 22 were deposited for each composition for a total of another 30 thin films 127 of PEDOT:PSS and DMSO and another 30 thin films 127 of PEDOT:PSS and EG.

The thin films 127 were then dried in an oven at 60° C. for 5 min and then cooled to 25° C. before being individually characterized.

Resistance measurements for each of the thin films 127 were obtained. Thin films 127 were measured in the x-, y- and z-directions. The z-direction measurements were obtained at three different points along the x-direction length of each thin film 127 and averaged to accommodate variations due to surface roughness. Conductivity of each thin film 127 was then determined based at least in part on the obtained resistance measurements and the x-, y- and z-direction measurements.

FIG. 8B depicts a conductivity map of each of the 30 thin films 127 of the first combination from 100% (by volume) PEDOT:PSS and 0% (by volume) DMSO down to 90% (by volume) PEDOT:PSS and 10% (by volume) DMSO in steps of 2% (by volume). FIG. 9B depicts a conductivity map of each of the 30 thin films 127 of the second combination from 100% (by volume) PEDOT:PSS and 0% (by volume) DMSO down to 90% (by volume) PEDOT:PSS and 10% (by volume) DMSO in steps of 2% (by volume).

FIG. 10A depicts a plot of conductivity as a function of composition for each of the 30 thin films 127 of the first combination from 100% (by volume) PEDOT:PSS and 0% (by volume) DMSO down to 90% (by volume) PEDOT:PSS and 10% (by volume) DMSO in steps of 2% (by volume) as represented by the circular data points. FIG. 10B depicts a plot of conductivity as a function of composition for each of the 30 thin films 127 of the second combination from 100% (by volume) PEDOT:PSS and 0% (by volume) DMSO down to 90% (by volume) PEDOT:PSS and 10% (by volume) DMSO in steps of 2% (by volume) as represented by the circular data points.

Such rapid enhancement and subsequent decline in film conductivity of thin films 127 from 100% (by volume) PEDOT:PSS down to 50% (by volume) PEDOT:PSS with both combinations, is in clear agreement with available literature and demonstrates that printhead 10, printer 50 and method 100 are capable of resolving precursors 20 to 2% (by volume) of the total volume being fed into dispenser 26. Besides the achievable resolution, it also illustrates the consistency of measured values with respect to the boundary values of the magnified range.

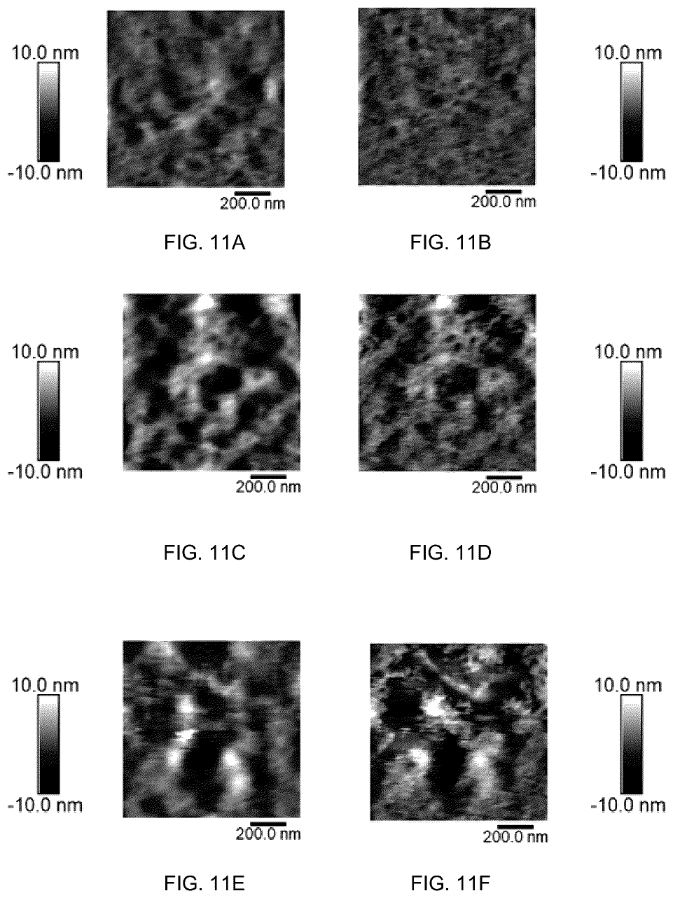

In addition to the conductivity evaluation discussed above, atomic force microscopy imaging was undertaken for 100% (by volume) PEDOT:PSS, a mixture of 90% (by volume) PEDOT:PSS and 10% (by volume) DMSO and a mixture of 90% (by volume) PEDOT:PSS and 10% (by volume) EG to validate the above-noted electrical measurements with expected morphological characteristics established in prior work. FIG. 11A is a morphology image of 100% (by volume) PEDOT:PSS while FIG. 11B is a phase image of 100% (by volume) PEDOT:PSS. FIG. 11C is a morphology image of the mixture of 90% (by volume) PEDOT:PSS and 10% (by volume) DMSO while FIG. 11D is a phase image of the mixture of 90% (by volume) PEDOT:PSS and 10% (by volume) DMSO. FIG. 11E is a morphology image of the mixture of 90% (by volume) PEDOT:PSS and 10% (by volume) EG while FIG. 11F is a phase image of the mixture of 90% (by volume) PEDOT:PSS and 10% (by volume) EG.

Based on a comparison of the morphological and phase images, the characterized morphological properties of the secondary doped PEDOT:PSS thin films printed using printhead 10, printer 50 and method 100 matched the expected results in the established literature thereby validating printhead 10, printer 50 and method 100 as tools for accelerated and consistent thin film library preparation and evaluation.

### Interpretation of Terms

Unless the context clearly requires otherwise, throughout the description and the claims:
“comprise”, “comprising”, and the like are to be construed in an inclusive sense, as opposed to an exclusive or exhaustive sense; that is to say, in the sense of “including, but not limited to”;
“connected”, “coupled”, or any variant thereof, means any connection or coupling, either direct or indirect, between two or more elements; the coupling or connection between the elements can be physical, logical, or a combination thereof; elements which are integrally formed may be considered to be connected or coupled;
“herein”, “above”, “below”, and words of similar import, when used to describe this specification, shall refer to this specification as a whole, and not to any particular portions of this specification;
“or”, in reference to a list of two or more items, covers all of the following interpretations of the word: any of the items in the list, all of the items in the list, and any combination of the items in the list;
the singular forms “a”, “an”, and “the” also include the meaning of any appropriate plural forms.

Words that indicate directions such as “vertical”, “transverse”, “horizontal”, “upward”, “downward”, “forward”, “backward”, “inward”, “outward”, “vertical”, “transverse”, “left”, “right”, “front”, “back”, “top”, “bottom”, “below”, “above”, “under”, and the like, used in this description and any accompanying claims (where present), depend on the specific orientation of the apparatus described and illustrated. The subject matter described herein may assume various alternative orientations. Accordingly, these directional terms are not strictly defined and should not be interpreted narrowly.

Although the operations of the method(s) herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

Where a component is referred to above, unless otherwise indicated, reference to that component (including a reference to a “means”) should be interpreted as including as equivalents of that component any component which performs the function of the described component (i.e. that is functionally equivalent), including components which are not structurally equivalent to the disclosed structure which performs the function in the illustrated exemplary embodiments of the invention.

Various features are described herein as being present in “some embodiments”. Such features are not mandatory and may not be present in all embodiments. Embodiments of the invention may include zero, any one or any combination of two or more of such features. This is limited only to the extent that certain ones of such features are incompatible with other ones of such features in the sense that it would be impossible for a person of ordinary skill in the art to construct a practical embodiment that combines such incompatible features. Consequently, the description that “some embodiments” possess feature A and “some embodiments” possess feature B should be interpreted as an express indication that the inventors also contemplate embodiments which combine features A and B (unless the description states otherwise or features A and B are fundamentally incompatible).

While a number of exemplary aspects and embodiments have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are consistent with the broadest interpretation of the specification as a whole.

The invention includes a number of non-limiting aspects. Non-limiting aspects of the invention include:
1. A method of combinatorial material screening, the method comprising:
   causing a first volume of a first precursor to travel through a first precursor channel into a mixing channel;
   causing a second volume of a second precursor to travel through a second precursor channel into the mixing channel;
   causing the first and second volumes of the first and second precursors to travel through the mixing channel to form a first mixture;
   depositing the first mixture onto a substrate to form a first thin film in a first pattern;
   causing a third volume of the first precursor to travel through the first precursor channel into the mixing channel;
   causing a fourth volume of the second precursor to travel through the second precursor channel into the mixing channel;
   causing the third and fourth volumes of the first and second precursors to travel through the mixing channel to form a second mixture;
   depositing the second mixture onto the substrate to form a second thin film in a second pattern; and
   comparing one or more characteristics of the first and second thin films.
2. A method according to aspect 1 or any other aspect herein wherein the first precursor channel comprises a first microfluidic channel, the second precursor channel comprises a second microfluidic channel and the mixing channel comprises a microfluidic mixing channel.
3. A method according to aspect 2 or any other aspect herein wherein the first microfluidic channel has a first cross-sectional area of between 100 μm² and 250,000 μm², the second microfluidic channel has a second cross-sectional area of between 100 μm² and 250,000 μm², and the third microfluidic channel has a third cross-sectional area of between 200 μm² and 500,000 μm².
4. A method according to aspect 2 or any other aspect herein wherein the first microfluidic channel has a first cross-sectional area of between 100 μm² and 10,000 μm², the second microfluidic channel has a second cross-sectional area of between 100 μm² and 10,000 μm², and the third microfluidic channel has a third cross-sectional area of between 200 μm² and 20,000 μm².
5. A method according to any one of aspects 1 to 4 or any other aspect herein wherein:
   causing the first volume of the first precursor to travel through the first precursor channel comprises controlling a first flow rate of the first precursor;
   causing the second volume of a second precursor to travel through the second precursor channel comprises controlling a second flow rate of the second precursor;
   causing the third volume of the first precursor to travel through the first precursor channel comprises controlling a third flow rate of the first precursor; and
   causing the fourth volume of the second precursor to travel through the second precursor channel comprises controlling a fourth flow rate of the second precursor.
6. A method according to aspect 5 or any other aspect herein wherein:
   controlling the first flow rate of the first precursor comprises controllably actuating a first syringe pump to force the first precursor into the first precursor channel at the first flow rate for a first period of time;
   controlling the second flow rate of the second precursor comprises controllably actuating a second syringe pump to force the second precursor into the second precursor channel at the second flow rate for a second period of time;
   controlling the third flow rate of the first precursor comprises controllably actuating the first syringe pump to force the first precursor into the first precursor channel at the third flow rate for a third period of time; and
   controlling the fourth flow rate of the second precursor comprises controllably actuating the second syringe pump to force the second precursor into the second precursor channel at the fourth flow rate for a fourth period of time.
7. A method according to aspect 5 or any other aspect herein wherein:
   controlling the first flow rate of the first precursor comprises controllably actuating a first syringe pump to force the first precursor into the first precursor channel based at least in part on feedback from a first sensor;
   controlling the second flow rate of the second precursor comprises controllably actuating a second syringe pump to force the second precursor into the second precursor channel based at least in part on feedback from a second sensor;
   controlling the third flow rate of the first precursor comprises controllably actuating the first syringe pump to force the first precursor into the first precursor channel based at least in part on feedback from the first sensor; and
   controlling the fourth flow rate of the second precursor comprises controllably actuating the second syringe pump to force the second precursor into the second precursor channel based at least in part on feedback from the second sensor.
8. A method according to any one of aspects 1 to 7 or any other aspect herein comprising flushing the mixing channel after depositing the first mixture onto the substrate.
9. A method according to aspect 8 or any other aspect herein wherein flushing the mixing channel comprises flushing water through the mixing channel.
10. A method according to any one of aspects 1 to 9 or any other aspect herein wherein after depositing the second mixture onto the substrate, the first mixture and the deposited mixture are heated to form the first thin film and the second thin film.
11. A method according to any one of aspects 1 to 9 or any other aspect herein wherein after depositing the second mixture onto the substrate, the first mixture and the deposited mixture are heated in a vacuum oven to form the first thin film and the second thin film.
12. A method according to any one of aspects 1 to 11 or any other aspect herein wherein after depositing the second mixture onto the substrate, the first mixture and the deposited mixture are subjected to ultraviolet light to form the first thin film and the second thin film.
13. A method according to any one of aspects 1 to 12 or any other aspect herein wherein:
   depositing the first mixture onto the substrate to form the first thin film in the first pattern comprises ejecting the first mixture through a nozzle and patterning the ejected first mixture onto the substrate with first magnetic fields; and
   depositing the second mixture onto the substrate to form the second thin film in the second pattern comprises ejecting the second mixture through the nozzle and patterning the ejected second mixture onto the substrate with second magnetic fields.
14. A method according to any one of aspects 1 to 12 or any other aspect herein wherein:
   depositing the first mixture onto the substrate to form the first thin film in the first pattern comprises inkjet printing the first mixture onto the substrate; and
   depositing the second mixture onto the substrate to form the second thin film in the second pattern comprises inkjet printing the second mixture onto the substrate.
15. A method according to any one of aspects 1 to 12 or any other aspect herein wherein:
   depositing the first mixture onto the substrate to form the first thin film in the first pattern comprises thermal triggered drop-on-demand printing the first mixture onto the substrate; and
   depositing the second mixture onto the substrate to form the second thin film in the second pattern comprises thermal triggered drop-on-demand printing the second mixture onto the substrate.
16. A method according to any one of aspects 1 to 12 or any other aspect herein wherein:
   depositing the first mixture onto the substrate to form the first thin film in the first pattern comprises piezoelectric triggered drop-on-demand printing the first mixture onto the substrate; and
   depositing the second mixture onto the substrate to form the second thin film in the second pattern comprises piezoelectric triggered drop-on-demand printing the second mixture onto the substrate.
17. A method according to any one of aspects 1 to 16 or any other aspect herein wherein:
   at least a portion of the step of depositing the first mixture onto the substrate overlaps temporally with the step of causing the first and second volumes of the first and second precursors to travel through the mixing channel; and
   at least a portion of the step of depositing the second mixture onto the substrate overlaps temporally with the step of causing the third and fourth volumes of the first and second precursors to travel through the mixing channel.
18. A method according to any one of aspects 1 to 17 or any other aspect herein wherein the first mixture has a first ratio of the first precursor to the second precursor and the second mixture has a second ratio of the first precursor to the second precursor wherein the second ratio is different from the first ratio.
19. A method according to any one of aspects 1 to 18 or any other aspect herein comprising:
   causing a fifth volume of a third precursor to travel through a third precursor channel into the mixing channel wherein causing the first and second volumes of the first and second precursors to travel through the mixing channel comprising causing the first, second and fifth volumes of the first, second and third precursors respectively to travel through the mixing channel to form the first mixture; and
   causing a sixth volume of the third precursor to travel through the third precursor channel into the mixing channel wherein causing the third and fourth volumes of the first and second precursors to travel through the mixing channel comprising causing the third, fourth and sixth volumes of the first, second and third precursors respectively to travel through the mixing channel to form the second mixture.
20. A method according to any one of aspects 1 to 19 or any other aspect herein wherein:
   the substrate comprises a plurality of electrodes;
   depositing the first mixture onto the substrate to form the first thin film in the first pattern comprises connecting first and second electrodes of the plurality of electrodes with the first mixture to thereby connect the first and second electrodes with the first thin film; and
   depositing the second mixture onto the substrate to form the second thin film in the second pattern comprises connecting third and fourth electrodes of the plurality of electrodes with the second mixture to thereby connect the third and fourth electrodes with the second thin film.
21. A method according to aspect 20 or any other aspect herein wherein the first thin film connecting the first and second electrodes has a first width and a first thickness and the second thin film connecting the third and fourth electrodes has a second width and a second thickness.
22. A method according to aspect 21 or any other aspect herein wherein the first width is different from the second width.
23. A method according to any one of aspects 21 and 22 or any other aspect herein wherein the first thickness is different from the second thickness.
24. A method according to any one of aspects 20 to 22 or any other aspect herein wherein the one or more characteristics comprise electrical characteristics.
25. A method according to any one of aspects 20 to 24 or any other aspect herein wherein comparing the one or more characteristics of the first and second thin films comprises determining a first resistance between the first and second electrodes and a second resistance between the third and fourth electrodes.
26. A method according to aspect 25 or any other aspect herein wherein comparing the one or more characteristics of the first and second thin films comprising determining a first conductivity based at least in part on the first width, the first thickness and the first resistance and determining a second conductivity based at least in part on the second width, the second thickness and the second resistance and comparing the first conductivity to the second conductivity.
27. A method according to aspect 25 or any other aspect herein wherein comparing the one or more characteristics of the first and second thin films comprising determining a first resistivity based at least in part on the first width, the first thickness and the first resistance and determining a second resistivity based at least in part on the second width, the second thickness and the second resistance and comparing the first resistivity to the second resistivity.
28. A method according to any one of aspects 1 to 27 or any other aspect herein wherein the one or more characteristics comprise physical characteristics.
29. A method according to aspect 28 or any other aspect herein wherein the physical characteristics comprise surface hardness.
30. A method according to any one of aspects 28 and 29 or any other aspect herein wherein the physical characteristics comprise surface roughness.
31. A method according to any one of aspects 28 and 90 or any other aspect herein wherein the physical characteristics comprise Young's Modulus.
32. A method according to any one of aspects 1 to 31 or any other aspect herein wherein the one or more characteristics comprise polymerization.
33. A method according to any one of aspects 1 to 32 or any other aspect herein wherein the one or more characteristics comprise time to set.
34. A method according to any one of aspects 1 to 33 or any other aspect herein wherein the one or more characteristics comprise degree of cross-linking.
35. A method according to any one of aspects 1 to 34 or any other aspect herein wherein the one or more characteristics comprise energy required to set.
36. A method according to any one of aspects 1 to 35 or any other aspect herein wherein the one or more characteristic comprise morphological characteristics.
37. A method according to any one of aspects 1 to 36 or any other aspect herein wherein the one or more characteristics comprise suitability for patterning.
38. A method according to any one of aspects 1 to 37 or any other aspect herein wherein the one or more characteristics comprise suitability for depositing by inkjet printing.
39. A method according to any one of aspects 1 to 38 or any other aspect herein wherein the one or more characteristics comprise suitability for depositing by thermal triggered drop-on-demand printing.
40. A method according to any one of aspects 1 to 39 or any other aspect herein wherein the one or more characteristics comprise suitability for depositing by piezoelectric triggered drop-on-demand printing.
41. A method according to any one of aspects 1 to 40 or any other aspect herein wherein depositing the second mixture onto the substrate to form the second thin film in the second pattern comprises depositing the second mixture on top of at least a portion of the first thin film on the substrate in the second pattern.
42. A method according to any one of aspects 1 to 41 or any other aspect herein wherein
   causing the first and second volumes of the first and second precursors to travel through the mixing channel to form the first mixture comprises allowing the first and second precursors to passively mix in the first mixing channel to form the first mixture; and
   causing the third and fourth volumes of the first and second precursors to travel through the mixing channel to form the second mixture comprises allowing the first and second precursors to passively mix in the first mixing channel to form the second mixture.
43. A method according to any one of aspects 1 to 41 or any other aspect herein wherein
   causing the first and second volumes of the first and second precursors to travel through the mixing channel to form the first mixture comprises actively mixing the first and second precursors in the first mixing channel to form the first mixture; and
   causing the third and fourth volumes of the first and second precursors to travel through the mixing channel to form the second mixture comprises actively mixing the first and second precursors in the first mixing channel to form the second mixture.
44. A method according to any one of aspects 1 to 41 or any other aspect herein wherein
   causing the first and second volumes of the first and second precursors to travel through the mixing channel to form the first mixture comprises agitating the first and second precursors in the first mixing channel to form the first mixture; and
   causing the third and fourth volumes of the first and second precursors to travel through the mixing channel to form the second mixture comprises agitating the first and second precursors in the first mixing channel to form the second mixture.
45. A method according to any one of aspects 1 to 41 or any other aspect herein wherein
   causing the first and second volumes of the first and second precursors to travel through the mixing channel to form the first mixture comprises vibrating the first and second precursors in the first mixing channel to form the first mixture; and
   causing the third and fourth volumes of the first and second precursors to travel through the mixing channel to form the second mixture comprises vibrating the first and second precursors in the first mixing channel to form the second mixture.
46. A method according to any one of aspects 1 to 41 or any other aspect herein wherein
   causing the first and second volumes of the first and second precursors to travel through the mixing channel to form the first mixture comprises mixing the first and second precursors in the first mixing channel by non-contact mixing to form the first mixture; and
   causing the third and fourth volumes of the first and second precursors to travel through the mixing channel to form the second mixture comprises mixing the first and second precursors in the first mixing channel by non-contact mixing to form the second mixture.
47. A method according to aspect 46 or any other aspect herein wherein
   mixing the first and second precursors in the first mixing channel by non-contact mixing to form the first mixture comprises actuating a non-contact mixer adjacent to the mixing channel; and
   mixing the first and second precursors in the first mixing channel by non-contact mixing to form the second mixture comprises actuating the non-contact mixer.
48. A method according to aspect 47 or any other aspect herein wherein the non-contact mixer is a haptic motor.
49. A method according to any one of aspects 47 and 48 or any other aspect herein wherein actuating the non-contact mixer comprises causing the mixing channel to vibrate.
50. A method according to any one of aspects 1 to 49 or any other aspect herein wherein the first precursor comprises a solution or a stabilized dispersion of one or more of an inorganic polymer, an organic polymer, an inorganic compound, an organometallic compound, a stoichiometric alloy (and/or components thereof), a biomaterial, a carbon allotrope and quantum dots.
51. A method according to any one of aspects 1 to 50 or any other aspect herein wherein the second precursor comprises one or more of an organic surfactant, an inorganic surfactant, a co-solvent, a binder and a diluent.
52. A method according to any one of aspects 1 to 51 or any other aspect herein wherein:
   depositing the first mixture onto the substrate to form the first thin film in the first pattern comprises controllably moving a printhead in one or more of x-, y- and z-directions to deposit the first mixture onto the substrate to form the first thin film in the first pattern; and
   depositing the second mixture onto the substrate to form the second thin film in the second pattern comprises controllably moving the printhead in one or more of the x-, y- and z-directions to deposit the second mixture onto the substrate to form the second thin film in the second pattern.
53. A method according to any one of aspects 1 to 52 or any other aspect herein wherein:
   depositing the first mixture onto the substrate to form the first thin film in the first pattern comprises controllably moving a stage supporting the substrate in one or more of x-, y- and z-directions to deposit the first mixture onto the substrate to form the first thin film in the first pattern; and
   depositing the second mixture onto the substrate to form the second thin film in the second pattern comprises controllably moving the stage in one or more of the x-, y- and z-directions to deposit the second mixture onto the substrate to form the second thin film in the second pattern.
54. A printhead for depositing material mixtures onto a substrate, the printhead comprising:
   a body defining a first precursor channel, a second precursor channel and a mixing channel;
   a first pump for forcing a controllable first volume of a first precursor through the first precursor channel into the mixing channel;
   a second pump for forcing a controllable second volume of a second precursor through the second precursor channel into the mixing channel;
   a mixer arranged to mix the first and second volumes of the first and second precursors in the mixing channel to form a first mixture;
   a dispenser for controllably depositing the first mixture onto the substrate in a first pattern.
55. A printhead according to aspect 54 or any other aspect herein wherein the dispenser comprises a drop-on-demand dispenser.
56. A printhead according to aspect 54 or any other aspect herein wherein the dispenser comprises a thermal triggered drop-on-demand dispenser.
57. A printhead according to aspect 54 or any other aspect herein wherein the dispenser comprises a piezoelectric drop-on-demand dispenser.
58. A printhead according to aspect 54 or any other aspect herein wherein the dispenser comprises an inkjet dispenser.
59. A printhead according to any one of aspects 54 to 59 or any other aspect herein wherein the first precursor channel comprises a first microfluidic channel, the second precursor channel comprises a second microfluidic channel and the mixing channel comprises a microfluidic mixing channel.
60. A printhead according to aspect 59 or any other aspect herein wherein the first microfluidic channel has a first cross-sectional area of between 100 μm² and 250,000 μm², the second microfluidic channel has a second cross-sectional area of between 100 μm² and 250,000 μm², and the third microfluidic channel has a third cross-sectional area of between 200 μm² and 500,000 μm².
61. A printhead according to aspect 59 or any other aspect herein wherein the first microfluidic channel has a first cross-sectional area of between 100 μm² and 10,000 μm², the second microfluidic channel has a second cross-sectional area of between 100 μm² and 10,000 μm², and the third microfluidic channel has a third cross-sectional area of between 200 μm² and 20,000 μm².
62. A printhead according to any one of aspects 54 to 61 or any other aspect herein wherein the mixer comprises a contact mixer.
63. A printhead according to any one of aspects 54 to 61 or any other aspect herein wherein the mixer comprises a non-contact mixer.
64. A printhead according to aspect 63 or any other aspect herein wherein the mixer comprises a haptic motor arranged adjacent to the mixing channel to controllably vibrate contents of the mixing channel.
65. A printhead according to aspect 63 or any other aspect herein wherein the mixer comprises a piezoelectric actuator arranged adjacent to the mixing channel to controllably vibrate contents of the mixing channel.
66. A printhead according to aspect 63 or any other aspect herein wherein the mixer comprises a surface acoustic wave actuator arranged adjacent to the mixing channel to controllably vibrate contents of the mixing channel.
67. A printhead according to any one of aspects 54 to 66 or any other aspect herein wherein the body defines a third channel and the printhead comprises:
   a third pump for forcing a controllable third volume of a third precursor through a third precursor channel into the mixing channel;
   wherein the mixer is arranged to mix the first, second and third volumes of the first, second and third precursors in the mixing channel to form the first mixture.
68. A printhead according to any one of aspects 54 to 67 or any other aspect herein wherein the body is 3D printed.
69. A printhead according to any one of aspects 54 to 68 or any other aspect herein wherein the body comprises an elastomeric material.
70. A printhead according to any one of aspects 54 to 69 or any other aspect herein wherein the first pump comprises a first syringe pump and the second pump comprises a second syringe pump.
71. A printhead according to any one of aspects 54 to 69 or any other aspect herein wherein the first pump comprises a first flow controlled pump and the second pump comprises a second flow controlled pump.
72. A printhead according to any one of aspects 54 to 69 or any other aspect herein wherein the first pump comprises a first pressure controlled pump and the second pump comprises a second pressure controlled pump.
73. A printhead according to any one of aspects 54 to 72 or any other aspect herein comprising a first sensor to provide feedback to the first pump to control a first rate of the first precursor through the first precursor channel and a second sensor to provide feedback to the first pump to control a second rate of the second precursor through the second precursor channel.
74. A combinatorial printer comprising:
   the printhead of any one of aspects 54 to 73 or any other aspect herein attached to a first actuator to controllably cause z-direction movement of the printhead; and
   a moveable stage for supporting the substrate wherein the moveable stage is attached to one or more second actuators to controllably cause x- and y-direction movement of the moveable stage;
   wherein the x-, y- and z-directions are mutually orthogonal.
75. A combinatorial printer comprising:
   the printhead of any one of aspects 54 to 73 or any other aspect herein attached to one or more actuators to controllably cause x-, y- and z-direction movement of the printhead;
   wherein the x-, y- and z-directions are mutually orthogonal.
76. A combinatorial printer comprising:
   the printhead of any one of aspects 54 to 73 or any other aspect herein; and
   a moveable stage for supporting the substrate wherein the moveable stage is attached to one or more actuators to controllably cause x-, y- and z-direction movement of the moveable stage;
   wherein the x-, y- and z-directions are mutually orthogonal.
77. Methods comprising any features, combinations of features and/or sub-combinations of features described herein or inferable therefrom.
78. Apparatus comprising any features, combinations of features and/or sub-combinations of features described herein or inferable therefrom.
79. Kits comprising any features, combinations of features and/or sub-combinations of features described herein or inferable therefrom.

Specific examples of systems, methods and apparatus have been described herein for purposes of illustration. These are only examples. The technology provided herein can be applied to systems other than the example systems described above. Many alterations, modifications, additions, omissions, and permutations are possible within the practice of this invention. This invention includes variations on described embodiments that would be apparent to the skilled addressee, including variations obtained by: replacing features, elements and/or acts with equivalent features, elements and/or acts; mixing and matching of features, elements and/or acts from different embodiments; combining features, elements and/or acts from embodiments as described herein with features, elements and/or acts of other technology; and/or omitting combining features, elements and/or acts from described embodiments.

1.-20. (canceled)

21. A method of combinatorial material screening, the method comprising:
causing a first volume of a first precursor to travel through a first precursor channel into a mixing channel;
causing a second volume of a second precursor to travel through a second precursor channel into the mixing channel;
causing the first and second volumes of the first and second precursors to travel through the mixing channel to form a first mixture;
depositing the first mixture onto a substrate to form a first thin film in a first pattern;
causing a third volume of the first precursor to travel through the first precursor channel into the mixing channel;
causing a fourth volume of the second precursor to travel through the second precursor channel into the mixing channel;
causing the third and fourth volumes of the first and second precursors to travel through the mixing channel to form a second mixture;
depositing the second mixture onto the substrate to form a second thin film in a second pattern; and
comparing one or more characteristics of the first and second thin films.

22. A method according to claim 21 wherein:
causing the first volume of the first precursor to travel through the first precursor channel comprises controlling a first flow rate of the first precursor;
causing the second volume of a second precursor to travel through the second precursor channel comprises controlling a second flow rate of the second precursor;
causing the third volume of the first precursor to travel through the first precursor channel comprises controlling a third flow rate of the first precursor; and
causing the fourth volume of the second precursor to travel through the second precursor channel comprises controlling a fourth flow rate of the second precursor.

23. A method according to claim 21 comprising flushing the mixing channel after depositing the first mixture onto the substrate.

24. A method according to claim 21 wherein:
depositing the first mixture onto the substrate to form the first thin film in the first pattern comprises printing the first mixture onto the substrate by one of: inkjet printing, thermal triggered drop-on-demand printing, and piezoelectric triggered drop-on-demand printing; and
depositing the second mixture onto the substrate to form the second thin film in the second pattern comprises printing the second mixture onto the substrate by one of: inkjet printing, thermal triggered drop-on-demand printing, and piezoelectric triggered drop-on-demand printing.

25. A method according claim 21 wherein:
at least a portion of the step of depositing the first mixture onto the substrate overlaps temporally with the step of causing the first and second volumes of the first and second precursors to travel through the mixing channel; and
at least a portion of the step of depositing the second mixture onto the substrate overlaps temporally with the step of causing the third and fourth volumes of the first and second precursors to travel through the mixing channel.

26. A method according to claim 21 wherein the first mixture has a first ratio of the first precursor to the second precursor and the second mixture has a second ratio of the first precursor to the second precursor wherein the second ratio is different from the first ratio.

27. A method according claim 21 comprising:
causing a fifth volume of a third precursor to travel through a third precursor channel into the mixing channel wherein causing the first and second volumes of the first and second precursors to travel through the mixing channel comprising causing the first, second and fifth volumes of the first, second and third precursors respectively to travel through the mixing channel to form the first mixture; and
causing a sixth volume of the third precursor to travel through the third precursor channel into the mixing channel wherein causing the third and fourth volumes of the first and second precursors to travel through the mixing channel comprising causing the third, fourth and sixth volumes of the first, second and third precursors respectively to travel through the mixing channel to form the second mixture.

28. A method according claim 21 wherein:
the substrate comprises a plurality of electrodes;
depositing the first mixture onto the substrate to form the first thin film in the first pattern comprises connecting first and second electrodes of the plurality of electrodes with the first mixture to thereby connect the first and second electrodes with the first thin film; and
depositing the second mixture onto the substrate to form the second thin film in the second pattern comprises connecting third and fourth electrodes of the plurality of electrodes with the second mixture to thereby connect the third and fourth electrodes with the second thin film.

29. A method according to claim 28 wherein the one or more characteristics comprise at least one of electrical characteristics and physical characteristics.

30. A method according to claim 28 wherein comparing the one or more characteristics of the first and second thin films comprises determining a first resistance between the first and second electrodes and a second resistance between the third and fourth electrodes.

31. A method according to claim 21 wherein the one or more characteristics comprise one or more of: surface hardness; surface roughness; Young's Modulus; polymerization; time to set; degree of cross-linking; energy required to set; morphological characteristics; suitability for patterning; suitability for depositing by inkjet printing; suitability for depositing by thermal triggered drop-on-demand printing; and suitability for depositing by piezoelectric triggered drop-on-demand printing.

32. A method according to claim 21 wherein depositing the second mixture onto the substrate to form the second thin film in the second pattern comprises depositing the second mixture on top of at least a portion of the first thin film on the substrate in the second pattern.

33. A method according to claim 21 wherein:
causing the first and second volumes of the first and second precursors to travel through the mixing channel to form the first mixture comprises agitating the first and second precursors in the first mixing channel to form the first mixture; and
causing the third and fourth volumes of the first and second precursors to travel through the mixing channel to form the second mixture comprises agitating or vibrating the first and second precursors in the first mixing channel to form the second mixture.

34. A method according to claim 21 wherein:
causing the first and second volumes of the first and second precursors to travel through the mixing channel to form the first mixture comprises mixing the first and second precursors in the first mixing channel by non-contact mixing to form the first mixture; and
causing the third and fourth volumes of the first and second precursors to travel through the mixing channel to form the second mixture comprises mixing the first and second precursors in the first mixing channel by non-contact mixing to form the second mixture.

35. A method according to claim 21 wherein the first precursor comprises a solution or a stabilized dispersion of one or more of an inorganic polymer, an organic polymer, an inorganic compound, an organometallic compound, a stoichiometric alloy (and/or components thereof), a biomaterial, a carbon allotrope and quantum dots.

36. A method according to claim 21 wherein the second precursor comprises one or more of an organic surfactant, an inorganic surfactant, a co-solvent, a binder and a diluent.

37. A printhead for depositing material mixtures onto a substrate, the printhead comprising:
a body defining a first precursor channel, a second precursor channel and a mixing channel;
a first pump for forcing a controllable first volume of a first precursor through the first precursor channel into the mixing channel;
a second pump for forcing a controllable second volume of a second precursor through the second precursor channel into the mixing channel;
a mixer arranged to mix the first and second volumes of the first and second precursors in the mixing channel to form a first mixture; and
a dispenser for controllably depositing the first mixture onto the substrate in a first pattern.

38. A printhead according to claim 37 wherein the first precursor channel comprises a first microfluidic channel, the second precursor channel comprises a second microfluidic channel and the mixing channel comprises a microfluidic mixing channel.

39. A printhead according to claim 37 wherein the mixer comprises one or more of: a contact mixer; a non-contact mixer; a haptic motor arranged adjacent to the mixing channel to controllably vibrate contents of the mixing channel; a piezoelectric actuator arranged adjacent to the mixing channel to controllably vibrate contents of the mixing channel; and a surface acoustic wave actuator arranged adjacent to the mixing channel to controllably vibrate contents of the mixing channel.

40. A printhead according to claim 37 wherein:
the first pump comprises one or more of: a first syringe pump; a first flow controlled pump; and a first pressure controlled pump; and
the second pump comprises one or more of: a second syringe pump; a second flow controlled pump; and a second pressure controlled pump.
